(19) United States
(12) Patent Application Publication
(10) Pub. No.: US 2026/0020362 A1
(43) Pub. Date: Jan. 15, 2026

(54) RIBBED SUBSTRATE AND OPTICAL SEMICONDUCTOR DEVICE

(71) Applicant: KANEKA CORPORATION, Osaka-shi, Osaka (JP)

(72) Inventors: Daiki Kinoshita, Settsu-shi (JP); Ayumu Ogawa, Settsu-shi (JP); Yuta Saito, Settsu-shi (JP)

(21) Appl. No.: 18/291,860

(22) PCT Filed: Aug. 4, 2022
(86) PCT No.: PCT/JP2022/029942

§ 371 Date: Jan. 30, 2025

(30) Foreign Application Priority Data
Aug. 6, 2021 (JP) 2021-130269

(51) Int. Cl. H10F 39/00; C08G 77/14; G03F 7/075

(52) U.S. Cl. CPC H10F 39/804; C08G 77/14; G03F 7/0757; H10F 39/011

(57) ABSTRACT

A ribbed substrate includes a transparent substrate and a rib member provided on one principal surface of the transparent substrate. The rib member is formed in a frame shape. An arithmetic mean roughness of an inner peripheral surface of the rib member is 50 nm or more and 3,000 nm or less. A value of a skewness of the inner peripheral surface of the rib member is preferably negative. The arithmetic mean roughness of the inner peripheral surface of the rib member is preferably 200 nm or more and 900 nm or less.

### TECHNICAL FIELD

The present invention relates to a ribbed substrate and an optical semiconductor device.

### BACKGROUND ART

Optical semiconductor devices such as CMOS sensors and CCD sensors are used in digital cameras, smartphones, and the like, and in recent years, the image sensors have been increasingly used and increasingly required to have a smaller size and higher definition along with the popularization of monitoring cameras in automobiles and factories.

An optical semiconductor device has, for example, a hollow structure in which a semiconductor substrate provided with a light receiving element and a glass substrate are bonded to each other with an adhesive. An optical semiconductor device having a hollow structure is obtained by, for example, applying a liquid adhesive such as an epoxy resin or an acrylic resin to a peripheral edge on a semiconductor substrate, installing a glass substrate as a sealing substrate, and then performing heating to cure the liquid adhesive. In addition, a method has been studied in which a photosensitive composition is used instead of a liquid adhesive for the purpose of improving pattern accuracy (see, for example, Patent Document 1).

An example of a method for manufacturing an optical semiconductor device using a photosensitive composition will be described below. First, a photosensitive composition is applied to one surface of a transparent substrate (for example, a glass substrate) to form a coating film on the transparent substrate. Subsequently, the coating film is irradiated with light through a photomask to form an exposed portion formed of the photosensitive composition in a semi-cured state and a non-exposed portion in the coating film. Subsequently, the non-exposed portion is removed from the transparent substrate with a developer to form a patterned coating film (rib member) in a semi-cured state on the transparent substrate, thereby obtaining a ribbed substrate (substrate including a transparent substrate and a rib member). Subsequently, the ribbed substrate and the semiconductor substrate are laminated such that the rib member-formed surface of the ribbed substrate and the semiconductor substrate face each other, and the rib member is cured to bond the transparent substrate and the semiconductor substrate. An optical semiconductor device having a hollow structure is obtained through the process described above.

### PRIOR ART DOCUMENT

### Patent Document

Patent Document 1: Japanese Patent Laid-Open Publication No. 2004-296453

### SUMMARY OF THE INVENTION

### Problems to be Solved by the Invention

However, as optical semiconductor devices have been required to have a smaller size and higher definition in recent years, there have been cases where imaging characteristics are affected in conventional optical semiconductor devices. In particular, there has been found a problem that when intense light is incident, optical noise (specifically, flares, ghosts, and the like) is generated in formed images, so that expected imaging characteristics cannot be sufficiently exhibited.

The present invention has been made in view of the above-described problems, and an object of the present invention is to provide a ribbed substrate and an optical semiconductor device which can suppress generation of optical noise.

### Means for Solving the Problems

### Aspects of the Invention

An aspect of the present invention is as follows.

[1] A ribbed substrate including:
a transparent substrate; and
a rib member provided on one principal surface of the transparent substrate, in which
the rib member is formed in a frame shape, and
an arithmetic mean roughness Ra of an inner peripheral surface of the rib member is 50 nm or more and 3,000 nm or less.

[2] The ribbed substrate according to [1], in which a value of a skewness Ssk of the inner peripheral surface of the rib member is negative.

[3] The ribbed substrate according to [1] or [2], in which the arithmetic mean roughness Ra of the inner peripheral surface of the rib member is 200 nm or more and 900 nm or less.

[4] The ribbed substrate according to any one of [1] to [3], in which a content ratio of a filler in the rib member is 30 wt % or less based on a total amount of the rib member.

[5] The ribbed substrate according to any one of [1] to [4], in which an arithmetic mean roughness Ra of an end surface of the rib member on a side opposite to the transparent substrate side is 50 nm or more and 3,000 nm or less.

[6] The ribbed substrate according to any one of [1] to [5], in which the transparent substrate is a glass substrate.

[7] The ribbed substrate according to any one of [1] to [6], in which the rib member includes a cured product of a photosensitive composition, and the photosensitive composition contains a curable compound having a polymerizable group, and a photopolymerization initiator, and has alkali solubility.

[8] The ribbed substrate according to [7], in which the photosensitive composition has a linear structure and a cyclic structure.

[9] The ribbed substrate according to [8], in which the photosensitive composition contains a polysiloxane compound having the linear structure.

[10] The ribbed substrate according to any one of [7] to [9], in which the photosensitive composition contains, as the curable compound, a compound having one or more cationically polymerizable groups selected from the group consisting of a glycidyl group and an alicyclic epoxy group.

[11] The ribbed substrate according to any one of [7] to [9], in which
the photosensitive composition contains, as the curable compound, a compound having one or more cationically polymerizable groups selected from the group consisting of a glycidyl group and an alicyclic epoxy group, and a compound having a radically polymerizable group, and
the photopolymerization initiator is a photoradical polymerization initiator.

[12] The ribbed substrate according to any one of [7] to [11], in which the photosensitive composition contains a compound having one or more alkali-soluble groups selected from the group consisting of a monovalent organic group of the following chemical formula (X1), a divalent organic group of the following chemical formula (X2), a phenolic hydroxyl group and a carboxy group.

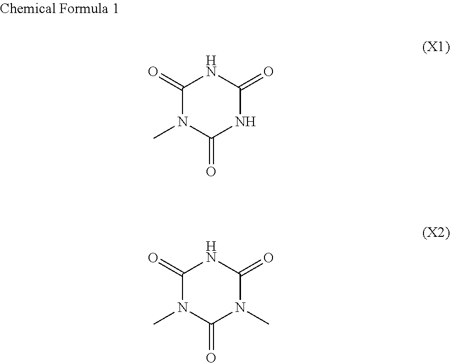

[13] An optical semiconductor device including:
the ribbed substrate according to any one of [1] to [12]; and
a semiconductor substrate provided with a light receiving element, in which
the transparent substrate of the ribbed substrate and the semiconductor substrate are laminated with the rib member of the ribbed substrate interposed therebetween, and
the rib member is provided so as to surround the light receiving element.

[14] The optical semiconductor device according to [13], further including an adhesive layer that bonds the rib member and the semiconductor substrate together.

### Effect of the Invention

According to the present invention, it is possible to provide a ribbed substrate and an optical semiconductor device which can suppress generation of optical noise.

### BRIEF DESCRIPTION OF THE DRAWINGS

FIG. 1 is a plan view showing an example of a ribbed substrate according to the present invention.

FIG. 2 is a sectional view taken along line II-II in FIG. 1.

FIG. 3 is a sectional view showing an example of an optical semiconductor device according to the present invention.

FIG. 4 is a partially enlarged sectional view showing another example of an optical semiconductor device according to the present invention.

FIG. 5 is a sectional view showing another example of an optical semiconductor device according to the present invention.

FIG. 6 is a partially enlarged sectional view showing another example of an optical semiconductor device according to the present invention.

FIG. 7 is a partially enlarged sectional view showing another example of an optical semiconductor device according to the present invention.

FIG. 8 is a sectional view showing another example of an optical semiconductor device according to the present invention.

FIG. 9 is a sectional view showing another example of an optical semiconductor device according to the present invention.

FIG. 10 is a plan view showing a transparent substrate after formation of a rib member in the manufacture of an example of an optical semiconductor device according to the present invention.

FIGS. 11A, 11B, and 11C are step-by-step sectional views showing a method for manufacturing an example of an optical semiconductor device according to the present invention.

FIGS. 12A, 12B, and 12C are step-by-step sectional views showing a method for manufacturing an example of an optical semiconductor device according to the present invention.

FIG. 13 is a plan view showing a semiconductor substrate after formation of a light receiving element in the manufacture of another example of an optical semiconductor device according to the present invention.

FIGS. 14A and 14B are step-by-step sectional views showing a method for manufacturing another example of an optical semiconductor device according to the present invention.

FIG. 15 is a plan view showing an example of a photomask.

FIG. 16 is a plan view showing another example of a photomask.

### MODE FOR CARRYING OUT THE INVENTION

Preferred embodiments of the present invention will be described in detail below, but the present invention is not limited to these embodiments. The academic documents and patent documents mentioned herein are incorporated herein by reference in their entirety.

First, terms used herein will be described. The “principal surface” of a layered material (more specifically, transparent substrate, semiconductor substrate or the like) refers to a surface perpendicular to the thickness direction of the layered material. The “arithmetic mean roughness Ra” is measured by a method described in JIS B 0601: 2013. The “skewness Ssk” is measured by a method described in JIS B 0681-2: 2018.

The term “polymerizable group” refers to a functional group which enables a polymerization reaction. The term “photopolymerization initiator” refers to a compound that generates an active species (specifically, radical, cation, anion, or the like) when irradiated with an active energy ray. The term “photocationic polymerization initiator” refers to a compound that generates a cation (acid) as an active species when irradiated with an active energy ray. The term “photoradical polymerization initiator” refers to a compound that generates a radical as an active species when irradiated with an active energy ray. Examples of the active energy ray include visible light rays, ultraviolet rays, infrared rays, electron beams, X-rays, α-rays, β-rays, and γ-rays.

The term “alkali-soluble group” refers to a functional group that enhances solubility in an alkaline solution by interacting with an alkali or reacting with an alkali. The phrase “a photosensitive composition has alkali-solubility” means that the photosensitive composition contains a compound having an alkali-soluble group.

The “polysiloxane compound” is a compound having a polysiloxane structure having a siloxane unit (Si—O—Si) as a constituent element. Examples of the polysiloxane structure include chain polysiloxane structures (specifically, linear polysiloxane structures, branched polysiloxane structures, and the like) and cyclic polysiloxane structures.

The term “cationically polymerizable group” refers to a functional group that causes a polymerization reaction in a chain reaction in the presence of a cation. The term “alicyclic epoxy group” refers to a functional group formed by bonding one oxygen atom to two adjacent carbon atoms among carbon atoms forming an alicyclic structure, and examples thereof include a 3,4-epoxycyclohexyl group. The term “radically polymerizable group” refers to a functional group having a radically polymerizable unsaturated bond.

The term “epoxy-based adhesive” refers to an adhesive containing a compound having an epoxy group (for example, a compound containing at least two epoxy groups in one molecule) as a main agent. The term “semi-cured state” refers to a state in which the degree of curing can be further increased by a subsequent step (for example, a heating step).

The “thickness” of each layer forming the optical semiconductor device is represented by an arithmetic mean of ten measured values obtained by selecting ten measurement locations at random from an electron microscope image of a cross-section of the optical semiconductor device cut in a thickness direction, and measuring thicknesses at the ten selected measurement locations.

Unless otherwise specified, the term “main component” of a material means a component contained in the material in the largest amount on a weight basis. The term “solid content” is a nonvolatile component in the composition, and the term “total solid content” means the total amount of composition constituent components excluding solvents.

Hereinafter, the name of a compound may be followed by the term “-based” to collectively refer to the compound and derivatives thereof. The term “-based” following the name of a compound to express the name of a polymer means that repeating units of the polymer are derived from the compound or a derivative thereof. Acryl and methacryl may be collectively referred to as “(meth)acryl.” Acrylate and methacrylate may be collectively referred to as “(meth)acrylate.” Acryloyl and methacryloyl may be collectively referred to as “(meth)acryloyl.”

Unless otherwise specified, one of the components, functional groups, and the like shown in the present description may be used alone, or two or more thereof may be used in combination.

In the drawings that are referred to in the following description, mainly relevant components are schematically shown for easy understanding, and the size, the number, the shape, and the like of each illustrated component may be different from the actual counterparts for convenience of preparing the drawings. For convenience of description, there may be cases where in the drawings that are described later, the same component parts as those in the drawings described previously are given the same symbols, and descriptions thereof are omitted.

### First Embodiment: Ribbed Substrate

A ribbed substrate according to a first embodiment of the present invention includes a transparent substrate, and a rib member provided on one principal surface of the transparent substrate. The rib member is formed in a frame shape. The arithmetic mean roughness Ra of the inner peripheral surface of the rib member is 50 nm or more and 3,000 nm or less.

The ribbed substrate according to the first embodiment can suppress generation of optical noise. The reason for this is presumed as follows.

In general, if intense light is incident on the optical semiconductor device, stray light is generated in a space inside the rib member (internal space of the rib member). The generated stray light is reflected by the inner peripheral surface of the rib member and incident on the light receiving element, resulting in generation of optical noise. On the other hand, in the ribbed substrate according to the first embodiment, the arithmetic mean roughness Ra of the inner peripheral surface of the rib member is 50 nm or more and 3,000 nm or less. Therefore, in an optical semiconductor device manufactured using the ribbed substrate according to the first embodiment, the generated stray light is diffusely reflected in reflection by the inner peripheral surface of the rib member. The diffusely reflected stray light is not so intense that optical noise is generated, and therefore, even if the stray light is incident on the light receiving element, the ribbed substrate according to the first embodiment enables suppression of generation of optical noise.

For further suppressing generation of optical noise, in the first embodiment, the arithmetic mean roughness Ra of the inner peripheral surface of the rib member is preferably 100 nm or more, more preferably 150 nm or more, still more preferably 200 nm or more, and may be 250 nm or more, 300 nm or more, or 350 nm or more.

For further suppressing generation of optical noise, in the first embodiment, the arithmetic mean roughness Ra of the inner peripheral surface of the rib member is preferably 2,000 nm or less, more preferably 1,500 nm or less, still more preferably 1,000 nm or less, even more preferably 900 nm or less, particularly preferably 850 nm or less.

For further suppressing generation of optical noise, in the first embodiment, the arithmetic mean roughness Ra of the inner peripheral surface of the rib member is preferably 200 nm or more and 900 nm or less, more preferably 250 nm or more and 900 nm or less, still more preferably 300 nm or more and 900 nm or less, even more preferably 350 nm or more and 900 nm or less, particularly preferably 350 nm or more and 850 nm or less.

For further suppressing generation of optical noise, in the first embodiment, the value of skewness Ssk of the inner peripheral surface of the rib member is preferably negative, more preferably −0.80 or more and −0.10 or less, still more preferably −0.70 or more and −0.10 or less, even more preferably −0.70 or more and −0.20 or less. The skewness Ssk indicates the symmetry of a height distribution with respect to an average level of the surfaces of irregularities. When the skewness Ssk is 0, the height distribution is a normal distribution (vertically symmetric). On the other hand, when the value of skewness Ssk is negative, the surface has many fine valleys, and when the skewness Ssk is a positive value, the surface has many fine mountains.

### [Configuration of Ribbed Substrate]

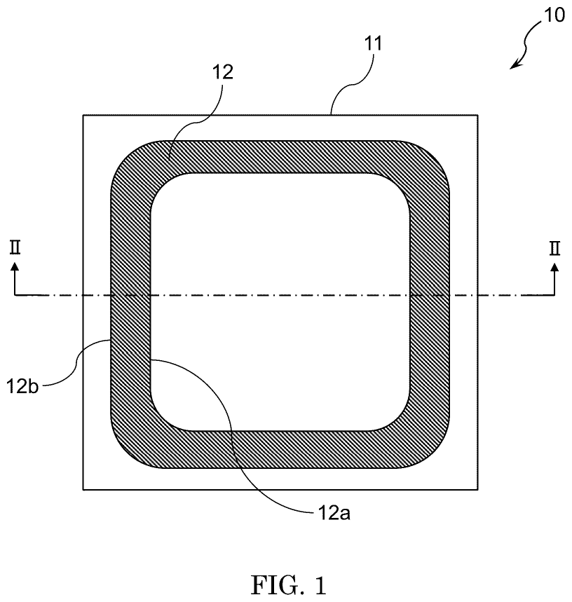

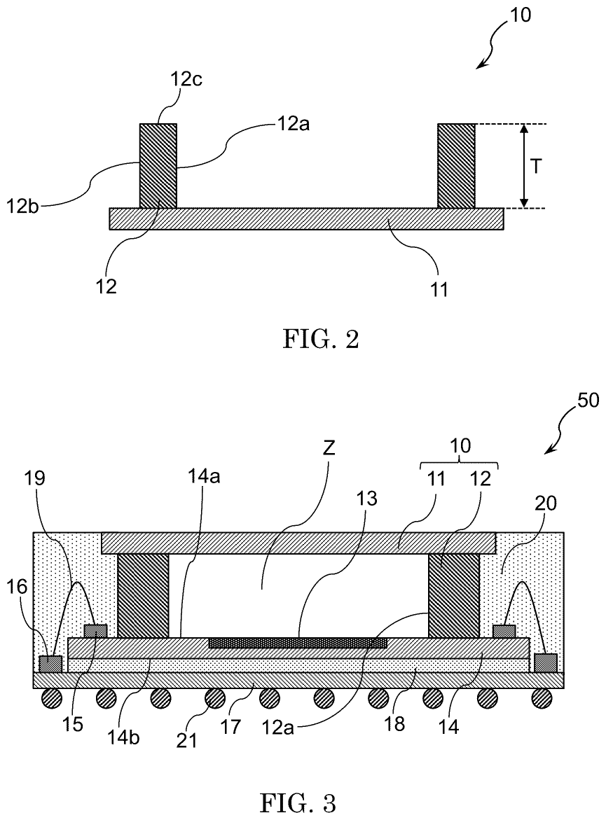

Hereinafter, an example of a configuration of a ribbed substrate according to the first embodiment will be described with reference to the drawings as appropriate. FIG. 1 is a plan view showing an example of a ribbed substrate according to the first embodiment. FIG. 2 is a sectional view taken along line II-II in FIG. 1.

As shown in FIGS. 1 and 2, a ribbed substrate 10 includes a transparent substrate 11, and a rib member 12 provided on one principal surface of the transparent substrate 11. The rib member 12 is formed in a frame shape. The arithmetic mean roughness Ra of an inner peripheral surface 12a of the rib member 12 is 50 nm or more and 3,000 nm or less.

The rib member 12 may be in a semi-cured state or in a cured state (state in which a semi-cured material is further cured). The rib member 12 in a semi-cured state has adhesiveness.

It is not necessary that the entire inner peripheral surface 12a of the rib member 12 be formed in an irregular shape (irregular shape having an arithmetic mean roughness Ra of 50 nm or more and 3,000 nm or less). Hereinafter, an irregular shape having an arithmetic mean roughness Ra of 50 nm or more and 3,000 nm or less is sometimes referred to simply as an “irregular shape.”

For further suppressing generation of optical noise, the ratio of the area of regions formed in an irregular shape in the inner peripheral surface 12a of the rib member 12 is preferably 50% or more, more preferably 80% or more, still more preferably 90% or more, particularly preferably 100% (the entire surface is formed in an irregular shape) when the total area of the inner peripheral surface 12a of the rib member 12 is defined as 100%.

For obtaining an optical semiconductor device excellent in reliability evaluated in a thermal shock test, a thickness T (height) of the rib member 12 is preferably 500 μm or less, more preferably 400 μm or less, still more preferably 300 μm or less, even more preferably 150 μm or less, and may be 140 μm or less, 130 μm or less, 120 μm or less, 110 μm or less, or 100 μm or less. For further suppressing generation of optical noise, the thickness T (height) of the rib member 12 is preferably 10 μm or more, more preferably 12 μm or more, still more preferably 15 μm or more, even more preferably 20 μm or more, particularly preferably 25 μm or more.

For obtaining a captured image having reduced strain, the variation in thickness T of the rib member 12 is preferably small. Specifically, the variation in thickness T of the rib member 12 is preferably within 20%, more preferably within 10% of the average value of the thicknesses T of the rib member 12 (for example, average value of the thicknesses T at 10 randomly selected measurement locations).

For further downsizing the optical semiconductor device while enhancing adhesion between the transparent substrate 11 and the rib member 12, the width of the rib member 12 is preferably 10 μm or more and 300 μm or less, more preferably 20 μm or more and 250 μm or less.

On an outer peripheral surface 12b of the rib member 12, an irregular shape (irregular shape having an arithmetic mean roughness Ra of 50 nm or more and 3,000 nm or less) may be formed, or is not required to be formed. When an irregular shape is formed on the outer peripheral surface 12b of the rib member 12, a contact area between the outer peripheral surface 12b and a sealing resin 20 (see FIG. 3) described later increases, so that adhesion between the outer peripheral surface 12b and the sealing resin 20 is improved.

For further improving adhesion between the outer peripheral surface 12b and the sealing resin 20, the arithmetic mean roughness Ra of the outer peripheral surface 12b is preferably 100 nm or more and 2,000 nm or less, more preferably 150 nm or more and 1,500 nm or less, still more preferably 200 nm or more and 1,000 nm or less, even more preferably 200 nm or more and 900 nm or less, and may be 250 nm or more and 900 nm or less, 300 nm or more and 900 nm or less, 350 nm or more and 900 nm or less, or 350 nm or more and 850 nm or less.

On an end surface 12c of the rib member 12 on a side opposite to the transparent substrate 11 side, an irregular shape (irregular shape having an arithmetic mean roughness Ra of 50 nm or more and 3,000 nm or less) may be formed, or is not required to be formed. Hereinafter, the end surface of the rib member on a side opposite to the transparent substrate side is sometimes referred to simply as an “end surface of the rib member”. If an irregular shape is formed on the end surface 12c of the rib member 12 when the rib member 12 and a semiconductor substrate 14 (see FIG. 3) are bonded with a later-described adhesive layer 301 (see FIG. 8) interposed therebetween, the contact area between the end surface 12c and the adhesive layer 301 increases, so that adhesion between the end surface 12c and the adhesive layer 301 is improved.

For further improving adhesion between the end surface 12c and the adhesive layer 301, the arithmetic mean roughness Ra of the end surface 12c of the rib member 12 is preferably 100 nm or more and 2,000 nm or less, more preferably 150 nm or more and 1,500 nm or less, still more preferably 200 nm or more and 1,000 nm or less, even more preferably 200 nm or more and 900 nm or less, and may be 250 nm or more and 900 nm or less, 300 nm or more and 900 nm or less, 350 nm or more and 900 nm or less, or 350 nm or more and 850 nm or less.

The shape of the rib member 12 is not particularly limited as long as it is a frame shape. As an example of the frame shape, the rib member 12 having a quadrangle-cylindrical structure is shown in FIGS. 1 and 2, but for example, a rib member having a circular-cylindrical structure may be used, or a rib member having a polygonal-cylindrical structure other than the quadrangle-cylindrical structure may be used.

When the rib member 12 has a quadrangular cylindrical structure, the shape of each of the four corners of the rib member 12 is preferably a curved shape. When the shape of each of the four corners of the rib member 12 is a curved shape, concentration of stress on the four corners can be lessened to reduce peeling and cracking of the rib member 12 during solder reflow and a thermal shock test. For further reducing peeling and cracking of the rib member 12 during solder reflow and a thermal shock test, the curvature radii of the four corners of the rib member 12 on the outer periphery side and the inner periphery side are each preferably 0.01 mm or more and 1.0 mm or less.

The irregular shape of the inner peripheral surface 12a of the rib member 12 may be an ordered irregular shape or a disordered irregular shape as long as the arithmetic mean roughness Ra is 50 nm or more and 3,000 nm or less. For further reducing optical noise, the irregular shape of the inner peripheral surface 12a is preferably a disordered irregular shape. When the irregular shape of the inner peripheral surface 12a is a disordered irregular shape, reflection light at the inner peripheral surface 12a can be more diffusely reflected.

On the inner peripheral surface 12a of the rib member 12 in the ribbed substrate 10, an irregular shape may be formed only in an X direction, an irregular shape may be formed only in a Y direction, or an irregular shape may be formed in both X and Y directions, where the X direction is a direction perpendicular to the thickness direction of the transparent substrate 11, and the Y direction is a direction parallel to the thickness direction of the transparent substrate 11. Here, the phrase “an irregular shape is formed only in the X direction (or the Y direction)” means that the irregular shape is observed only when scanning is performed in the X direction (or the Y direction), and the irregular shape is not observed when scanning is performed in a direction perpendicular to the X direction (or the Y direction). For further reducing optical noise, it is preferable that the inner peripheral surface 12a of the rib member 12 has an irregular shape formed in both the X and Y directions.

Hereinafter, the arithmetic mean roughness Ra of an irregular shape observed by scanning in a direction perpendicular to the thickness direction of the transparent substrate (X direction) is sometimes referred to as an “arithmetic mean roughness Ra in a direction perpendicular to the thickness direction of the transparent substrate.” The arithmetic mean roughness Ra of an irregular shape observed by scanning in a direction parallel to the thickness direction of the transparent substrate (Y direction) is sometimes referred to as an “arithmetic mean roughness Ra in a direction parallel to the thickness direction of the transparent substrate.” In the present specification, unless otherwise specified, the numerical value of the arithmetic mean roughness Ra of the inner peripheral surface of the rib member is represented by the larger one of the numerical value of the arithmetic mean roughness Ra in a direction perpendicular to the thickness direction of the transparent substrate and the numerical value of the arithmetic mean roughness Ra in a direction parallel to the thickness direction of the transparent substrate.

The method for forming an irregular shape on the inner peripheral surface 12a, the outer peripheral surface 12b, and the end surface 12c of the rib member 12 is not particularly limited, and examples thereof include a method in which the rib member 12 is formed from a material containing a filler, a method in which irregularities are formed using a mold, a method in which a photomask having irregularities is used in patterning of a photosensitive composition by photolithography, and a method in which by photolithography, the rib member 12 is formed from a photosensitive composition having a linear structure and a structure other than a linear structure.

In particular, a method in which by photolithography, the rib member 12 is formed from a photosensitive composition having a linear structure and a structure other than a linear structure is preferable because fine irregularities can be formed, the number of steps can be reduced, and a high-precision pattern shape can be easily formed. When by photolithography, the rib member 12 is formed from a photosensitive composition having a linear structure and a structure other than a linear structure, an irregular shape can be formed on the inner peripheral surface 12a, the outer peripheral surface 12b, and the end surface 12c of the rib member 12. The reason for this may be that when a photosensitive composition having a linear structure and a structure other than a linear structure is used, a phase separation structure is developed in the photosensitive composition before the development step in photolithography, so that irregularities derived from the phase separation structure are formed on the inner peripheral surface 12a, the outer peripheral surface 12b, and the end surface 12c of the rib member 12 after the development step.

Examples of the “structure other than a linear structure” include a branched chain structure, a network structure, and a cyclic structure, and for easily adjusting the arithmetic mean roughness Ra to be within the range of 50 nm or more and 3,000 nm or less, the structure other than a linear structure is preferably a cyclic structure. The “photosensitive composition having a linear structure and a structure other than a linear structure” may contain a compound having a linear structure and a compound having a structure other than a linear structure, or may contain a compound having both a linear structure and a structure other than a linear structure. Examples of the compound having a linear structure include polysiloxane compounds having both a linear structure and a structure other than a linear structure, linear polysiloxane compounds, linear polyacrylate, linear polyether, linear polyester, linear polyimide, and linear polyolefin, and from the viewpoint of heat resistance, polysiloxane compounds having both a linear structure and a structure other than a linear structure or linear polysiloxane compounds are preferable.

When by photolithography, the rib member 12 is formed from a photosensitive composition having a linear structure and a structure other than a linear structure, the values of skewness Ssk of the inner peripheral surface 12a, the outer peripheral surface 12b, and the end surface 12c of the rib member 12 tend to be negative. On the other hand, when the rib member 12 is formed from a material containing a filler, the values of skewness Ssk of the inner peripheral surface 12a, the outer peripheral surface 12b, and the end surface 12c of the rib member 12 tend to be positive. Details of the photosensitive composition will be described later.

When the rib member 12 is formed from a material containing a filler, the content ratio of the filler in the resulting rib member 12 is preferably 30 wt % or less based on the total amount of the rib member 12. When the content ratio of the filler in the rib member 12 is 30 wt % or less, foreign matter derived from the filler can be inhibited from remaining between patterns during patterning by photolithography. For easily forming an irregular shape on a surface of the rib member 12 while suppressing the remaining of foreign matter between patterns, the content ratio of the filler in the rib member 12 is preferably 0.5 wt % or more and 30 wt % or less, more preferably 0.5 wt % or more and 20 wt % or less, still more preferably 0.5 wt % or more and 10 wt % or less based on the total amount of the rib member 12.

### [Element of Ribbed Substrate]

Next, elements of the ribbed substrate according to the first embodiment will be described.

### (Transparent Substrate 11)

As the transparent substrate 11, for example, a glass substrate, a transparent plastic substrate (more specifically, an acrylic resin substrate, a polycarbonate substrate or the like), or the like can be used, and a glass substrate is preferable from the viewpoint of reliability. The type of glass is not particularly limited, and examples thereof include quartz glass, borosilicate glass, and alkali-free glass. The thickness of the transparent substrate 11 is, for example, 50 μm or more and 2,000 μm or less.

If necessary, a covering film functioning as any of an infrared reflection film (or an infrared cut filter), an antireflection film (AR coating), an anti-reflection film, a protective film, a reinforcing film, a shielding film, a conductive film, an antistatic film, a low-pass filter, a high-pass filter, and a band-pass filter may be formed on a surface of the transparent substrate 11. In particular, an anti-reflection film and an infrared reflection film (or an infrared cut filter) are preferable because optical noise of a captured image is further reduced.

In particular, when an antireflection film is used as the covering film, it is preferable to use a multi-layer anti-reflection film containing one or more inorganic materials selected from the group consisting of TiO₂, Nb₂O₅, Ta₂O₅, CaF₂, SiO₂, Al₂O₃, MgS₂, ZrO₂, NiO, and MgF₂.

The covering film can be provided on one principal surface or both principal surfaces of the transparent substrate 11. When the covering films are provided on both principal surfaces, the types of the covering films may be the same or different. Different types of covering films having the same function can also be stacked on one principal surface. Different types of covering films having different functions can also be stacked on one principal surface. The number of stacked layers is not particularly limited, and a multi-layer film having several to several ten layers may be formed.

### (Rib Member 12)

The material for the rib member 12 is not particularly limited as long as the material allows the arithmetic mean roughness Ra of the inner peripheral surface 12a of the rib member 12 to be adjusted to 50 nm or more and 3,000 nm or less. Examples thereof include cured products of photosensitive compositions and cured products of thermosetting resins, and cured products of photosensitive compositions are preferable from the viewpoint of ease of patterning. That is, from the viewpoint of ease of patterning, it is preferable that the rib member 12 includes a cured product of the photosensitive composition.

### [Photosensitive Composition]

Next, a photosensitive composition usable as a material for the rib member 12 will be described. Examples of the photosensitive composition usable as the material for the rib member 12 include photosensitive compositions which contain a curable compound having a polymerizable group and a photopolymerization initiator and have alkali solubility. Examples of the polymerizable group include cationically polymerizable groups such as an epoxy group, an oxetanyl group, a vinyl ether group, and an alkoxysilyl group, and radically polymerizable groups having a radically polymerizable unsaturated bond. From the viewpoint of the storage stability of the photosensitive composition, the cationically polymerizable group is preferably one or more selected from the group consisting of a glycidyl group, an alicyclic epoxy group and an oxetanyl group, more preferably one or more selected from the group consisting of a glycidyl group and an alicyclic epoxy group. Specific examples of the radically polymerizable group include a (meth)acryloyl group and a vinyl group. The curable compound having a polymerizable group may have one or both of a cationically polymerizable group and a radically polymerizable group in one molecule. A compound having a cationically polymerizable group and a compound having a radically polymerizable group may be used in combination.

The photosensitive composition contains a compound having an alkali-soluble group. The alkali-soluble group is preferably one or more selected from the group consisting of a monovalent organic group represented by the following chemical formula (X1) (hereinafter, sometimes referred to as an “X1 group”), a divalent organic group represented by the following chemical formula (X2) (hereinafter, sometimes referred to as an “X2 group”), a phenolic hydroxyl group, and a carboxy group. The X1 group is a monovalent organic group derived from a N-mono-substituted isocyanuric acid. The X2 group is a divalent organic group derived from a N,N-disubstituted isocyanuric acid.

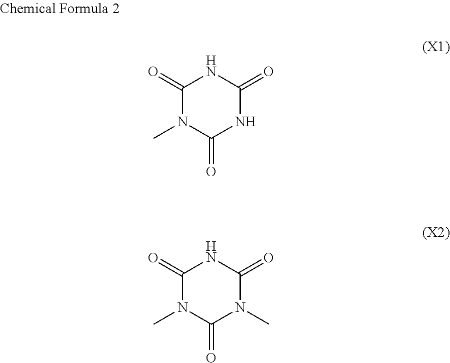

For forming the rib member 12 which is excellent in heat resistance, the alkali-soluble group is preferably one or more selected from the group consisting of the X1 group and the X2 group.

For forming the rib member 12 which is excellent in heat resistance, it is preferable that the photosensitive composition contains a polysiloxane compound. Hereinafter, preferred examples of the photosensitive composition containing a polysiloxane compound will be described.

The photosensitive composition that is preferable as a material for the rib member 12 (hereinafter, sometimes referred to as a “specific photosensitive composition”) contains a polysiloxane compound having a cationically polymerizable group and an alkali-soluble group in one molecule (hereinafter, sometimes referred to as “component (A)”), and a photopolymerization initiator (hereinafter, sometimes referred to as “component (B)”). The component (A) is an example of a curable compound having a polymerizable group.

### {Component (A)}

The component (A) is not particularly limited as long as it is a polysiloxane compound having a cationically polymerizable group and an alkali-soluble group in one molecule. When the component (A) has a cationically polymerizable group and an alkali-soluble group in one molecule, a specific photosensitive composition excellent in both developability and curability can be obtained. Preferably, the component (A) has a plurality of cationically polymerizable groups in one molecule. When the component (A) has a plurality of cationically polymerizable groups in one molecule, there is a tendency that the rib member 12 having a high crosslinking density is obtained, resulting in further improvement of the heat resistance of the rib member 12. A plurality of cationically polymerizable groups may be the same, or two or more different functional groups. Preferably, the component (A) has a plurality of alkali-soluble groups in one molecule. When the component (A) has a plurality of alkali-soluble groups in one molecule, developability tends to be further improved because non-exposed portion removability is enhanced during development. A plurality of alkali-soluble groups may be the same, or two or more different functional groups.

The component (A) may have a chain polysiloxane structure or a cyclic polysiloxane structure. For forming the rib member 12 having further excellent heat resistance, it is preferable that the component (A) has a cyclic polysiloxane structure. When the component (A) has a cyclic polysiloxane structure, the specific photosensitive composition tends to have high film formability and developability.

The component (A) may have a polysiloxane structure in the main chain or a polysiloxane structure in the side chain. For forming the rib member 12 having further excellent heat resistance, it is preferable that the component (A) has a polysiloxane structure in the main chain. For forming the rib member 12 having furthermore excellent heat resistance, it is preferable that the component (A) has a cyclic polysiloxane structure in the main chain.

The cyclic polysiloxane structure may be a monocyclic structure or a polycyclic structure. The polycyclic structure may be a polyhedral structure. The rib member 12 having high hardness and excellent heat resistance tends to be obtained when the content ratio of T units (XSiO_{3/2}) or the Q units (SiO_{4/2}) among siloxane units forming a ring is high. The rib member 12 which is more flexible and has reduced residual stress tends to be obtained when the content ratio of M units (X₃SiO_{1/2}) or the D units (X₂SiO_{2/2}) is high.

When the component (A) is a polymer having a polysiloxane structure in the main chain, the weight average molecular weight of the polymer is preferably 10,000 or more and 50,000 or less, more preferably 10,000 or more and 40,000 or less, still more preferably 10,000 or more and 35,000 or less, even more preferably 10,000 or more and 30,000 or less, and may be 10,000 or more and 25,000 or less, or 15,000 or more and 25,000 or less. When the weight average molecular weight is 10,000 or more, the heat resistance of the obtained rib member 12 tends to be further improved. On the other hand, when the weight average molecular weight is 50,000 or less, developability tends to be further improved.

Examples of the cationically polymerizable group of the component (A) include an epoxy group, a vinyl ether group, an oxetanyl group, and an alkoxysilyl group. From the viewpoint of the storage stability of the specific photosensitive composition, the cationically polymerizable group is preferably one or more selected from the group consisting of a glycidyl group, an alicyclic epoxy group, and an oxetanyl group, more preferably one or more selected from the group consisting of a glycidyl group and an alicyclic epoxy group. Among them, an alicyclic epoxy group is particularly preferable because it is excellent in photocationic polymerizability.

Examples of the alkali-soluble group of the component (A) include an X1 group, an X2 group, a phenolic hydroxyl group, and a carboxy group. For forming the rib member 12 having excellent heat resistance, the alkali-soluble group of the component (A) is preferably one or more selected from the group consisting of the X1 group and the X2 group.

The method for introducing the cationically polymerizable group into the polysiloxane compound is not particularly limited, and a method using a hydrosilylation reaction is preferable because a cationically polymerizable group can be introduced into a polysiloxane compound via a chemically stable silicon-carbon bond (Si—C bond). In other words, the component (A) is preferably a polysiloxane compound which is organically modified by a hydrosilylation reaction and into which a cationically polymerizable group is introduced via a silicon-carbon bond. Preferably, the alkali-soluble group is also introduced into the polysiloxane compound via a silicon-carbon bond by a hydrosilylation reaction.

The component (A) is obtained by, for example, a hydrosilylation reaction using the following compounds (α), (β), and (γ) as starting substances.
Compound (α): a polysiloxane compound having at least two SiH groups (hydrosilyl groups) in one molecule.
Compound (β): a compound having a carbon-carbon double bond having reactivity with a SiH group and a cationically polymerizable group in one molecule.
Compound (γ): a compound having a carbon-carbon double bond having reactivity with a SiH group and an alkali-soluble group in one molecule.

### (Compound (α))

The compound (α) is a polysiloxane compound having at least two SiH groups in one molecule, and it is possible to used, for example, a compound disclosed in WO 96/15194, which has at least two SiH groups in one molecule. Specific examples of the compound (α) include hydrosilyl group-containing polysiloxanes having a linear structure, polysiloxanes having a hydrosilyl group at a molecular terminal, and a cyclic polysiloxanes containing a hydrosilyl group (hereinafter, sometimes referred to simply as “cyclic polysiloxane”). The cyclic polysiloxane may have a polycyclic structure, and the polycyclic structure may be a polyhedral structure. For forming the rib member 12 having high heat resistance and mechanical strength, it is preferable that a cyclic polysiloxane compound having at least two SiH groups in one molecule is used as the compound (α). The compound (α) is preferably a cyclic polysiloxane having three or more SiH groups in one molecule. From the viewpoint of heat resistance and light resistance, the group present on the Si atom is preferably a hydrogen atom or a methyl group.

Examples of the hydrosilyl group-containing polysiloxane having a linear structure include a copolymers of a dimethylsiloxane unit with a methylhydrogensiloxane unit and a terminal trimethylsiloxy unit, copolymers of a diphenylsiloxane unit with a methylhydrogensiloxane unit and a terminal trimethylsiloxy unit, copolymers of a methylphenylsiloxane unit with a methylhydrogensiloxane unit and a terminal trimethylsiloxy unit, and polysiloxanes terminally blocked with a dimethylhydrogensilyl group.

Examples of the polysiloxane having a hydrosilyl group at a molecular terminal include polysiloxanes terminally blocked with a dimethylhydrogensilyl group, and polysiloxanes including a dimethylhydrogensiloxane unit (H(CH₃)₂SiO_{1/2} unit) and one or more siloxane units selected from the group consisting of a SiO₂ unit, a SiO_{3/2} unit and a SiO unit.

The cyclic polysiloxane is represented by, for example, the following general formula I.

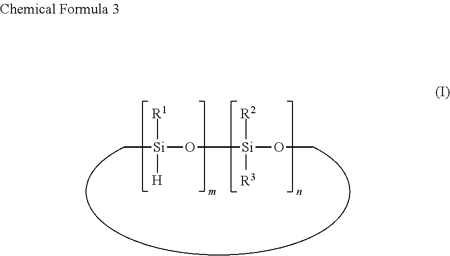

In the general formula I, R¹, R², and R³ each independently represent a monovalent organic group having 1 or more and 20 or less carbon atoms, m represents an integer of 2 or more and 10 or less, and n represents an integer of 0 or more and 10 or less. For easily carrying out the hydrosilylation reaction, m is preferably 3 or more. For easily carrying out the hydrosilylation reaction, m+n is preferably 3 or more and 12 or less. For easily carrying out the hydrosilylation reaction, n is preferably 0.

R¹, R², and R³ are each preferably an organic group having one or more elements selected from the group consisting of C, H, and O. Examples of R¹, R², and R³ include alkyl groups, hydroxyalkyl groups, alkoxyalkyl groups, oxyalkyl groups, and aryl groups. Among them, chain alkyl groups such as a methyl group, an ethyl group, a propyl group, a hexyl group, an octyl group, a decyl group, and a dodecyl group; cyclic alkyl groups such as cyclohexyl groups and norbornyl groups; or a phenyl group is preferable. From the viewpoint of availability of the cyclic polysiloxane, R¹, R², and R³ are each preferably a chain alkyl group having 1 or more and 6 or less carbon atoms, or a phenyl group. For easily carrying out the hydrosilylation reaction, R¹, R², and R³ are each preferably a chain alkyl group, more preferably a chain alkyl group having 1 or more and 6 or less carbon atoms, still more preferably a methyl group.

Examples of the cyclic polysiloxane represented by the general formula (I) include 1,3,5,7-tetrahydrogen-1,3,5,7-tetramethylcyclotetrasiloxane, 1-propyl-3,5,7-trihydrogen-1,3,5,7-tetramethylcyclotetrasiloxane, 1,5-dihydrogen-3,7-dihexyl-1,3,5,7-tetramethylcyclotetrasiloxane, 1,3,5-trihydrogen-1,3,5-trimethylcyclotrisiloxane, 1,3,5,7,9-pentahydrogen-1,3,5,7,9-pentamethylcyclopentasiloxane, and 1,3,5,7,9,11-hexahydrogen-1,3,5,7,9,11-hexamethylcyclohexasiloxane. Among them, 1,3,5,7-tetrahydrogen-1,3,5,7-tetramethylcyclotetrasiloxane (a compound of the general formula (I) in which m is 4, n is 0, and R¹ is a methyl group) is preferable from the viewpoint of availability, and reactivity of the SiH group.

The compound (α) is obtained by a known synthesis method. The cyclic polysiloxane represented by the general formula I can be synthesized by, for example, a method disclosed in WO 96/15194 A or the like. The cyclic polysiloxane having a polyhedral backbone can be synthesized by, for example, a method described in Japanese Patent Laid-Open Publication No. 2004-359933, Japanese Patent Laid-Open Publication No. 2004-143449, Japanese Patent Application Laid-Open Publication No. 2006-269402, or the like. As the compound (α), a commercially available polysiloxane compound may be used.

For forming the rib member 12 further excellent in heat resistance while enhancing the developability of the specific photosensitive composition, the content ratio of the structural unit derived from the compound (α) in the component (A) is preferably 10 wt % or more and 50 wt % or less, more preferably 15 wt % or more and 45 wt % or less, based on 100 wt % of the component (A).

### (Compound (β))

The compound (β) has a carbon-carbon double bond having reactivity with a SiH group (hydrosilyl group) and a cationically polymerizable group in one molecule, and is used for introducing a cationically polymerizable group into a polysiloxane compound. The cationically polymerizable group in the compound (β), together with its preferred aspects, is the same as described above for the cationically polymerizable group of the component (A). That is, the compound (β) has preferably one or more selected from the group consisting of a glycidyl group, an alicyclic epoxy group and an oxetanyl group, more preferably one or more selected from the group consisting of a glycidyl group and an alicyclic epoxy group, still more preferably has an alicyclic epoxy group, as the cationically polymerizable group.

Examples of the group containing a carbon-carbon double bond having reactivity with a SiH group (hereinafter, sometimes referred to simply as an “alkenyl group”) include a vinyl group, an allyl group, a methallyl group, an allyloxy group (—O—CH₂—CH═CH₂), a 2-allylphenyl group, a 3-allylphenyl group, a 4-allylphenyl group, a 2-(allyloxy)phenyl group, a 3-(allyloxy) phenyl group, a 4-(allyloxy)phenyl group, a 2-(allyloxy)ethyl group, a 2,2-bis(allyloxymethyl)butyl group, a 3-allyloxy-2,2-bis (allyloxymethyl)propyl group, and a vinyl ether group. From the viewpoint of reactivity with a SiH group, the compound (β) has preferably one or more selected from the group consisting of a vinyl group, an allyl group and an allyloxy group, more preferably one or more selected from the group consisting of a vinyl group and an allyl group, as the alkenyl group.

Specific examples of the compound (β) include 1-vinyl-3,4-epoxycyclohexane, allyl glycidyl ether, allyl oxetanyl ether, diallyl monoglycidyl isocyanurate, and monoallyl diglycidyl isocyanurate. From the viewpoint of reactivity in cationic polymerization, the compound (β) is preferably a compound having one or more functional groups selected from the group consisting of an alicyclic epoxy group and a glycidyl group, more preferably a compound having an alicyclic epoxy group. For further enhancing the reactivity in cationic polymerization, the compound (β) is preferably one or more compounds selected from the group consisting of diallyl monoglycidyl isocyanurate and 1-vinyl-3,4-epoxycyclohexane, more preferably 1-vinyl-3,4-epoxycyclohexane.

For forming the rib member 12 further excellent in heat resistance while enhancing the developability of the specific photosensitive composition, the content ratio of the structural unit derived from the compound (β) in the component (A) is preferably 10 wt % or more and 50 wt % or less, more preferably 12 wt % or more and 45 wt % or less, based on 100 wt % of the component (A).

### (Compound (γ))

The compound (γ) has a carbon-carbon double bond having reactivity with a SiH group and an alkali-soluble group in one molecule, and is used for introducing an alkali-soluble group into a polysiloxane compound. The alkali-soluble group in the compound (γ), together with its preferred aspects, is the same as described above for the alkali-soluble group of the component (A). That is, it is preferable that the compound (γ) preferably has one or more selected from the group consisting of an X1 group and an X2 group as the alkali-soluble group.

The compound (γ) has a group containing a carbon-carbon double bond having reactivity with a SiH group (alkenyl group). Examples of the alkenyl group of the compound (γ), together with its preferred aspects, include those exemplified above for the alkenyl group of the compound (β). That is, the compound (γ) has preferably one or more selected from the group consisting of a vinyl group, an allyl group and an allyloxy group, more preferably one or more selected from the group consisting of a vinyl group and an allyl group, as the alkenyl group.

The compound (γ) may have two or more alkenyl groups in one molecule. When the compound (γ) contains a plurality of alkenyl groups in one molecule, a plurality of compounds (a) can be crosslinked by the hydrosilylation reaction, and therefore the crosslinking density of the resulting cured product tends to increase, resulting in improvement of the heat resistance of the cured product.

Specific examples of the compound (γ) include diallyl isocyanurate, monoallyl isocyanurate, 2,2′-diallyl bisphenol A, vinylphenol, allylphenol, butenoic acid, pentenoic acid, hexenoic acid, heptenoic acid, and undecylenic acid.

For obtaining a specific photosensitive composition which is excellent in developability, the compound (γ) is preferably one or more selected from the group consisting of diallyl isocyanurate, monoallyl isocyanurate and 2,2′-diallyl bisphenol A, more preferably one or more selected from the group consisting of diallyl isocyanurate and monoallyl isocyanurate. When monoallyl isocyanurate is used as the compound (γ), a component (A) having the X1 group as an alkali-soluble group is obtained. When diallyl isocyanurate is used as the compound (γ), a component (A) having the X2 group as an alkali-soluble group is obtained.

For obtaining a specific photosensitive composition further excellent in developability, the content ratio of the structural unit derived from the compound (γ) in the component (A) is preferably 5 wt % or more and 50 wt % or less, more preferably 10 wt % or more and 30 wt % or less, based on 100 wt % of the component (A).

### (Other Starting Substances)

In addition to the compound (α), compound (β) and compound (γ), other starting substances may be used in the hydrosilylation reaction. For example, an alkenyl group-containing compound which is different from the compound (β) and compound (γ) (hereinafter, sometimes referred to as “another alkenyl group-containing compound”) may be used as the other starting substance.

For introducing a radically polymerizable group into the component (A), it is preferable that a compound having an alkenyl group and a (meth)acryloyl group in one molecule (hereinafter, sometimes referred to as a “compound (δ)”) is used as another alkenyl group-containing compound. When the compound (δ) is used, the component (A) can be photoradically polymerized because a (meth)acryloyl group is introduced into the component (A).

Specific examples of the compound (δ) include vinyl acrylate, vinyl methacrylate, allyl acrylate, allyl methacrylate, 2-butenyl acrylate, and 2-butenyl methacrylate.

For enhancing reactivity in photoradical polymerization, the content ratio of the structural unit derived from the compound (δ) in the component (A) is preferably 5 wt % or more and 30 wt % or less, more preferably 8 wt % or more and 20 wt % or less, based on 100 wt % of the component (A).

For obtaining the rib member 12 further excellent in heat resistance, it is preferable to use a compound having two or more alkenyl groups in one molecule (hereinafter, sometimes referred to as a “compound (ε)”) as another alkenyl group-containing compound. When the compound (ε) is used, the heat resistance of the resulting rib member 12 tends to be further improved because the number of crosslinking points increases during the hydrosilylation reaction.

Specific examples of the compound (ε) include diallyl phthalate, triallyl trimellitate, diethylene glycol bisallyl carbonate, 1,1,2,2-tetraallyloxyethane, triallyl cyanurate, triallyl isocyanurate, diallyl monobenzyl isocyanurate, diallyl monomethyl isocyanurate, 1,2,4-trivinylcyclohexane, triethylene glycol divinyl ether, divinylbenzene, divinylbiphenyl, 1,3-diisopropenylbenzene, 1,4-diisopropenylbenzene, 1,3-bis(allyloxy)adamantane, 1,3-bis(vinyloxy)adamantane, 1,3,5-tris(allyloxy)adamantane, 1,3,5-tris(vinyloxy)adamantane, dicyclopentadiene, vinylcyclohexene, 1,5-hexadiene, 1,9-decadiene, diallyl ether, and oligomers thereof.

For further improving the heat resistance of the resulting rib member 12, the compound (ε) is preferably one or more selected from the group consisting of triallyl isocyanurate and diallyl monomethyl isocyanurate, more preferably diallyl monomethyl isocyanurate.

For enhancing alkali developability while further improving the heat resistance of the resulting rib member 12, the content ratio of the structural unit derived from the compound (ε) in the component (A) is preferably 1 wt % or more and 30 wt % or less, more preferably 3 wt % or more and 20 wt % or less, based on 100 wt % of the component (A).

For adjusting the skewness Ssk of the inner peripheral surface 12a of the rib member 12 to a negative value by forming phase separation structure-derived irregularities on the inner peripheral surface 12a, it is preferable that a linear polysiloxane compound having an alkenyl group at both ends (hereinafter, sometimes referred to as a “compound (ζ)”) is used as another alkenyl group-containing compound, and cyclic polysiloxane is used as the compound (α). When the value of skewness Ssk of the inner peripheral surface 12a of the rib member 12 is negative, generation of optical noise tends to be further suppressed. When the compound (ζ) is used, a polysiloxane compound having a linear structure is obtained as the component (A). When cyclic polysiloxane is used as the compound (α), and the compound (ζ) is used, a specific photosensitive composition having a linear structure and a cyclic structure is obtained. That is, when cyclic polysiloxane is used as the compound (α), and the compound (ζ) is used, a linear structure part (compound (ζ)-derived linear structure part) and a cyclic structure part (cyclic polysiloxane-derived cyclic structure part) are introduced into the component (A). Specific examples of the compound (ζ) include a compound represented by the following general formula Y

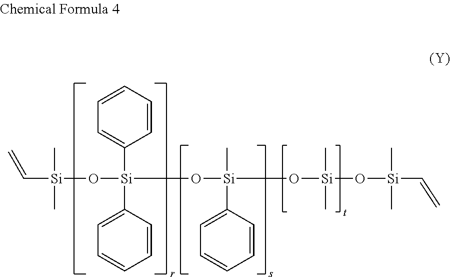

In the general formula Y, the ratio of r, s, and t (r:s:t) is a substance amount ratio of the structural units. For example, r+s+t=100. In the general formula Y, the arrangement of the structural units is not particularly limited.

For further suppressing generation of optical noise, the weight average molecular weight of the compound (ζ) is preferably 1,000 or more and 30,000 or less, and more preferably 2,000 or more and 29,000 or less.

For further suppressing generation of optical noise, the content ratio of the structural unit derived from the compound (ζ) in the component (A) is preferably 1.0 wt % or more and 10.0 wt % or less, more preferably 1.2 wt % or more and 5.0 wt % or less, based on 100 wt % of the component (A).

The compound (ζ) may be blended in the specific photosensitive composition. That is, the compound (ζ) may be used as a component other than the component (A) and the component (B) (other component described later) instead of the starting material for the component (A). Even when the compound (ζ) is used as other component of the specific photosensitive composition and a cyclic polysiloxane is used as the compound (α), the skewness Ssk of the inner peripheral surface 12a can be adjusted to a negative value. Since the compound (ζ) is a polysiloxane compound having a linear structure, a specific photosensitive composition having a linear structure and a cyclic structure is obtained even when a cyclic polysiloxane is used as the compound (α) and the compound (ζ) is used as other component of the specific photosensitive composition. When a specific photosensitive composition containing the compound (ζ) as other component is used, irregularities derived from a phase separation structure tend to increase on the inner peripheral surface 12a of the rib member 12 as compared to a case where a specific photosensitive composition containing the component (A) obtained using the compound (ζ) as one of starting materials is used.

For further increasing the irregularities of the inner peripheral surface 12a of the rib member 12, it is preferable that the specific photosensitive composition contains both the component (A) having a linear structure portion derived from the compound (ζ) and the compound (ζ) as other component.

When the specific photosensitive composition contains the compound (ζ) as other component, the content ratio of the compound (ζ) in the specific photosensitive composition is preferably 1 wt % or more and 5 wt % or less based on the total solid content of the specific photosensitive composition for further suppressing generation of optical noise. When the specific photosensitive composition contains the compound (ζ) as other component, the compound (ζ) functions as, for example, a crosslinking agent that crosslinks the components (A) during curing of the rib member 12.

The arithmetic mean roughness Ra of the inner peripheral surface 12a, the outer peripheral surface 12b and the end surface 12c of the rib member 12, and the skewness Ssk of the inner peripheral surface 12a of the rib member 12 can be adjusted by, for example, changing at least one of the content ratio of structural units derived from the compound (ζ) in the component (A), the weight average molecular weight of the compound (ζ), and the content ratio of the compound (ζ) as other component in the specific photosensitive composition.

### (Hydrosilylation Reaction)

The order and the method of the hydrosilylation reaction for obtaining the component (A) are not particularly limited. For example, the component (A) is obtained by a hydrosilylation reaction conforming to a method disclosed in WO 2009/075233 and using the compound (α), the compound (β), the compound (γ), and other starting substances as optional components if necessary. The component (A) obtained using the compound (α), the compound (β), the compound (γ), and other starting substances as optional components if necessary is, for example, a polymer having a plurality of cationically polymerizable groups and a plurality of alkali-soluble groups in one molecule, and a polysiloxane structure in the main chain.

The proportion of each compound in the hydrosilylation reaction is not particularly limited, but the total amount A of alkenyl groups and the total amount B of SiH groups in the starting substance preferably satisfy 1≤B/A≤30, and more preferably satisfy 1≤B/A≤10.

In the hydrosilylation reaction, a hydrosilylation catalyst such as chloroplatinic acid, a platinum-olefin complex, or a platinum-vinylsiloxane complex may be used. The hydrosilylation catalyst and a co-catalyst may be used in combination. The addition amount (substance amount) of the hydrosilylation catalyst is not particularly limited, and is preferably 10⁻⁸ or more and 10⁻¹ or less times, more preferably 10⁻⁶ or more and 10⁻² or less times the total substance amount of alkenyl groups contained in the starting substance.

The temperature of the hydrosilylation reaction may be appropriately set, and is preferably 30° C. or higher and 200° C. or lower, more preferably 50° C. or higher and 150° C. or lower. The oxygen concentration of the gas phase portion in the hydrosilylation reaction is preferably 3 vol % or less. From the viewpoint of accelerating the hydrosilylation reaction, the gas phase portion may contain oxygen in an amount of 0.1 vol % or more and 3 vol % or less.

A solvent may be used in the hydrosilylation reaction. As the solvent, a single solvent or a mixture of two or more solvents can be used. Examples of the solvent that can be used include hydrocarbon-based solvents such as benzene, toluene, xylene, hexane, and heptane; ether-based solvents such as tetrahydrofuran, 1,4-dioxane, 1,3-dioxolane, and diethyl ether; ketone-based solvents such as acetone and methyl ethyl ketone; halogen-based solvents such as chloroform, methylene chloride, and 1,2-dichloroethane. Toluene, xylene, tetrahydrofuran, 1,4-dioxane, 1,3-dioxolane, or chloroform is preferable because it is easily distilled off after the reaction. In the hydrosilylation reaction, a gelling inhibitor may be used if necessary.

For further suppressing generation of optical noise, the content ratio of the component (A) in the specific photosensitive composition is preferably 20 wt % or more and 97 wt % or less based on the total solid content of the specific photosensitive composition.

### {Component (B)}

The component (B) is preferably one or more selected from the group consisting of a photocationic polymerization initiator and a photoradical polymerization initiator. Since the specific photosensitive composition contains the component (A) having a cationically polymerizable group, the component (A) can be crosslinked by photocationic polymerization when the specific photosensitive composition contains a photocationic polymerization initiator as the component (B). In the case where the component (A) having a (meth)acryloyl group is used or when a component (C) described later is used, the component (A) or the component (C) can be crosslinked by photoradical polymerization when the specific photosensitive composition contains a photoradical polymerization initiator as the component (B). The specific photosensitive composition may contain both a photocationic polymerization initiator and a photoradical polymerization initiator as the component (B).

### (Photocationic Polymerization Initiator)

As the photocationic polymerization initiator, for example, a known photocationic polymerization initiator can be used. The photocationic polymerization initiator is not particularly limited, and examples thereof include various compounds which are considered suitable in Japanese Patent Laid-open Publication No. 2000-1648, National Publication of International Patent Application No. 2001-515533, and WO 2002/83764. The photocationic polymerization initiator is preferably a sulfonate ester-based compound, a carboxylic acid ester-based compound, or an onium salt-based compound, more preferably an onium salt-based compound, still more preferably a sulfonium salt-based compound.

As the sulfonate ester-based compound, various sulfonic acid derivatives can be used, and examples thereof include disulfone-based compounds, disulfonyldiazomethane-based compounds, disulfonylmethane-based compounds, sulfonylbenzoylmethane-based compounds, imidosulfonate-based compounds, benzoin sulfonate-based compounds, pyrogallol trisulfonate-based compounds, and benzyl sulfonate-based compounds. These compounds can be used alone, or in combination of two or more thereof. In the present invention, a carboxylic acid ester-based compound can also be used as the photocationic polymerization initiator.

Examples of the onium salt-based compound include sulfonium salt-based compounds and iodonium salt-based compounds.

The photocationic polymerization initiators listed in descending order in terms of acid strength of the acid generated are as follows: compounds containing SbF₆⁻ as an anion, compounds containing B(C₆F₅)₄⁻ as an anion, compounds containing PF₆⁻ as an anion, compounds containing CF₃SO₃⁻ as an anion, and compounds containing HSO₄⁻ as an anion. When a photocationic polymerization initiator which generates an acid having high acid strength is used, the residual film ratio tends to increase. The pKa of the acid generated from the photocationic polymerization initiator is preferably less than 3, more preferably less than 1.

Examples of the cation of the sulfonium salt-based compound include cations represented by the following chemical formula II.

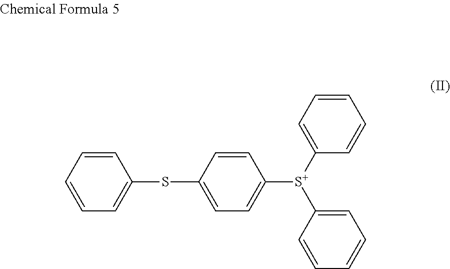 [SMILES: c1ccc(Sc2ccc([S+](c3ccccc3)c3ccccc3)cc2)cc1]

Examples of the commercially available product of the sulfonium salt-based compound (sulfonium salt-based photocationic polymerization initiator) include a photocationic polymerization initiator containing a fluoroalkyl fluorophosphate (anion) and a cation represented by chemical formula II (“CPI-210S” manufactured by San-Apro Ltd).

The content ratio of the photocationic polymerization initiator in the specific photosensitive composition is not particularly limited. From the viewpoint of the balance between the curing rate and the physical properties of the cured product, the content ratio of photocationic polymerization initiator is preferably 0.1 wt % or more and 10 wt % or less, more preferably 1 wt % or more and 5 wt % or less, based on the total solid content of the specific photosensitive composition.

If necessary, a thermal cationic polymerization initiator (a compound that generates a cation due to heat) may be blended in the specific photosensitive composition. Examples of the thermal cationic polymerization initiator include sulfonium salt-based compounds, iodonium salt-based compounds, benzothiazonium salt-based compounds, ammonium salt-based compounds, and phosphonium salt-based compounds. Among them, sulfonium salt-based compounds and benzothiazonium salt-based compounds are preferably used.

### (Photoradical Polymerization Initiator)

Examples of the photoradical polymerization initiator include acetophenone-based compounds, acylphosphine oxide-based compounds, benzoin-based compounds, benzophenone-based compounds, α-diketone-based compounds, biimidazole-based compounds, polynuclear quinone-based compounds, triazine-based compounds, oxime ester-based compounds, titanocene-based compounds, xanthone-based compounds, thioxanthone-based compounds, ketal-based compounds, azo-based compounds, peroxides, 2,3-dialkyldione-based compounds, disulfide-based compounds, and fluoroamine-based compounds. From the viewpoint of ease of patterning, the photoradical polymerization initiator is preferably one or more selected from the group consisting of an acetophenone-based compound, a benzophenone-based compound and an oxime ester-based compound, more preferably a benzophenone-based compound.

Examples of the benzophenone-based compound include benzyl dimethyl ketone, benzophenone, 4,4′-bis(dimethylamino)benzophenone, and 4,4′-bis(diethylamino)benzophenone.

The content ratio of the photoradical polymerization initiator in the specific photosensitive composition is not particularly limited. From the viewpoint of the balance between the curing rate and the physical properties of the cured product, the content ratio of photoradical polymerization initiator is preferably 0.1 wt % or more and 5 wt % or less, more preferably 0.5 wt % or more and 1 wt % or less, based on the total solid content of the specific photosensitive composition.

If necessary, a thermal radical polymerization initiator (a compound that generates a radical due to heat) may be blended in the specific photosensitive composition. Specific examples of the thermal radical polymerization initiator include acetyl peroxide, benzoyl peroxide, methyl ethyl ketone peroxide, cyclohexanone peroxide, hydrogen peroxide, t-butyl hydroperoxide, cumene hydroperoxide, di-t-butyl peroxide, dicumyl peroxide, dilauroyl peroxide, t-butyl peroxyacetate, t-butyl peroxypivalate, azobisisobutyronitrile, azobisisovaleronitrile, ammonium persulfate, sodium persulfate, and potassium persulfate. One of these thermal radical polymerization initiators may be used alone, or two or more thereof may be used in combination.

### {Solvent}

The specific photosensitive composition may contain a solvent. For example, the component (A), the component (B), and other components used if necessary as described later are dissolved or dispersed in a solvent to obtain a specific photosensitive composition.

Specific examples of the solvent include hydrocarbon-based solvents such as benzene, toluene, hexane, and heptane; ether-based solvents such as tetrahydrofuran, 1,4-dioxane, 1,3-dioxolane, and diethyl ether; ketone-based solvents such as acetone, methyl ethyl ketone, methyl isobutyl ketone, and cyclohexanone; glycol-based solvents such as propylene glycol 1-monomethyl ether 2-acetate, diethylene glycol dimethyl ether, diethylene glycol ethyl methyl ether, and ethylene glycol diethyl ether; ester-based solvents such as isobutyl isobutyrate; and halogen-based solvents such as chloroform, methylene chloride, and 1,2-dichloroethane. From the viewpoint of the applicability (film formation stability) of the specific photosensitive composition, the solvent is preferably a glycol-based solvent, more preferably propylene glycol 1-monomethyl ether 2-acetate.

From the viewpoint of applicability (film formation stability) of the specific photosensitive composition, the amount of the solvent is preferably 0.5 parts by weight or more and 100 parts by weight or less, more preferably 1 part by weight or more and 50 parts by weight or less, based on 100 parts by weight of the component (A).

### {Other Components}

The specific photosensitive composition may contain components other than the above-described component (A) and component (B) (other components) as a solid content (components other than the solvent) as long as the purpose and the effects of the present invention are not impaired. However, for forming the rib member 12 which is excellent in heat resistance while enabling further suppression of generation of optical noise, the total content ratio of the component (A) and the component (B) is preferably 50 wt % or more, more preferably 60 wt % or more, still more preferably 70 wt % or more and 100 wt % or less, based on the total solid content of the specific photosensitive composition.

Examples of the other component include the compound (C), a compound having a radically polymerizable group, a reactive diluent, a sensitizer, a polymer dispersant, a thermoplastic resin, a filler, a crosslinker, a basic compound, an adhesiveness improver, a coupling agent (silane coupling agent or the like), an antioxidant, a radical scavenger, a colorant, a mold release agent, a flame retardant, a flame retardant promoter, a surfactant, an antifoaming agent, an emulsifier, a leveling agent, a cissing inhibitor, an ion trapping agent (antimony-bismuth or the like), a thixotropy imparting agent, a tackifier, a storage stability improver, an ozone degradation inhibitor, a light stabilizer, a thickener, a plasticizer, a heat stabilizer, a conductivity imparting agent, an antistatic agent, a radiation blocking agent, a nucleating agent, a phosphorus-based peroxide decomposer, a lubricant, a metal deactivator, a thermal conductivity imparting agent, and a physical property modifier.

### (Compound Having Radically Polymerizable Group)

The specific photosensitive composition may contain a compound having a radically polymerizable group (hereinafter, sometimes referred to as a “component (C)”) as the other component. Since the component (C) is the other component (a component other than the component (A) and the component (B)), the component (C) has a radically polymerizable group and does not have a siloxane unit. The specific photosensitive composition containing the component (C) tends to be excellent in deep-curing (property of being photocrosslinkable even at a deep part) in patterning. When the rib member 12 is formed by photolithography using the specific photosensitive composition containing the component (C), the taper angle described later can be easily adjusted to more than 90°.

Examples of the component (C) include compounds having a radically polymerizable unsaturated bond (ethylenically unsaturated bond or the like). Examples of the group containing the ethylenically unsaturated bond include a (meth)acryloyl group and a vinyl group.

Specific examples of the component (C) include allyl (meth)acrylate, vinyl (meth)acrylate, dicyclopentenyl (meth)acrylate, dicyclopentenyloxyethyl (meth)acrylate, (meth)acrylate-modified allyl glycidyl ether (“Denacol (registered trademark) Acrylate DA111” manufactured by Nagase ChemteX Corporation), urethane (meth)acrylate-based compounds, epoxy (meth)acrylate-based compounds, trimethylolpropane tri(meth)acrylate, pentaerythritol tetra(meth)acrylate, ditrimethylolpropane tetra(meth)acrylate, dipentaerythritol hexa(meth)acrylate, butanediol di(meth)acrylate, nonanediol di(meth)acrylate, polypropylene glycol (meth)acrylate, bisphenol A di(meth)acrylate, tris(2-(meth)acryloyloxyethyl) isocyanurate, and caprolactone-modified tris-(2-acryloxyethyl) isocyanurate (“A-9300-1CL” manufactured by Shin-Nakamura Chemical Co., Ltd.).

For obtaining an optical semiconductor device which further suppresses generation of optical noise and is excellent in reliability, the content ratio of the component (C) in the specific photosensitive composition is preferably 1 wt % or more and 50 wt % or less, more preferably 5 wt % or more and 40 wt % or less, still more preferably 10 wt % or more and 30 wt % or less, based on the total solid content of the specific photosensitive composition.

When the photosensitive composition as a material for the rib member 12 contains a curable compound having a cationically polymerizable group (preferably, one or more cationically polymerizable groups selected from the group consisting of a glycidyl group and an alicyclic epoxy group) (hereinafter, sometimes referred to as a “cationic polymerizable compound”), the component (C), and a photoradical polymerization initiator, the semi-cured state of the rib member 12 can be stably maintained. The reason for this is presumed as follows.

In patterning by photolithography using a photosensitive composition containing a cationically polymerizable compound, the component (C) and a photoradical polymerization initiator (hereinafter, sometimes referred to as a “cation-radical-combined photosensitive composition”), only radicals are generated as an active species by irradiation with an active energy ray, and the component (C) in the exposed portion is radically polymerized, whereby the rib member 12 in a semi-cured state can be formed without generating cations. Thus, a cation-radical-combined photosensitive composition enables suppression of further curing of the rib member 12 by remaining cations even if the ribbed substrate 10 including the rib member 12 in a semi-cured state is stored for a long time until being laminated with the semiconductor substrate 14. Therefore, when the rib member 12 is formed using a cation-radical-combined photosensitive composition, the semi-cured state of the rib member 12 can be stably maintained. For bonding the ribbed substrate 10 and the semiconductor substrate 14 to each other, the semiconductor substrate 14 and the transparent substrate 11 (transparent substrate 11 in the ribbed substrate 10) are laminated with the rib member 12 interposed therebetween while the rib member 12 is maintained in a semi-cured state, and the resulting laminated product is then heated to cationically polymerize the cationically polymerizable compound in the rib member 12, so that the semiconductor substrate 14 and the transparent substrate 11 can be bonded.

### (Filler)

The specific photosensitive composition may contain a filler. When the specific photosensitive composition contains a filler, the arithmetic mean roughness Ra of the inner peripheral surface 12a of the rib member 12 can be easily adjusted. The filler is not particularly limited, and examples of the filler that can be used include inorganic fillers such as silica-based fillers (quartz, fumed silica, precipitated silica, anhydrous silicic acid, fused silica, crystalline silica, ultrafine amorphous silica, and the like), silicon nitride, silver powder, alumina, aluminum hydroxide, titanium oxide, glass fiber, carbon fiber, mica, carbon black, graphite, diatomaceous earth, white clay, clay, talc, calcium carbonate, magnesium carbonate, barium sulfate, and inorganic balloons, and organic fillers such as epoxy-based fillers. Among them, silica-based fillers (silica particles) are preferable from the viewpoint of availability.

For enhancing adhesion between the transparent substrate 11 and the semiconductor substrate 14 while improving the patterning property of the specific photosensitive composition, it is preferable that the specific photosensitive composition is free of a filler.

### (Radical Scavenger)

The specific photosensitive composition may contain a radical scavenger. When the specific photosensitive composition contains a radical scavenger, active radicals generated by irradiation with an active energy ray are inhibited from diffusing to a non-exposed portion during patterning. As a result, curing of the non-exposed portion is suppressed, so that it is possible to suppress generation of residues after development (for example, a non-exposed portion remaining without being removed by development).

Examples of the radical scavenger include 4-hydroxy-2,2,6,6-tetramethylpiperidine-1-oxyl, 2,2,6,6-tetramethylpiperidine-1-oxyl, 4-amino-2,2,6,6-tetramethylpiperidine-1-oxyl, 4-cyano-2,2,6,6-tetramethylpiperidine-1-oxyl, 4-benzoxy-2,2,6,6-tetramethylpiperidine-1-oxyl, 4-methoxy-2,2,6,6-tetramethylpiperidine-1-oxyl, 4-oxo-2,2,6,6-tetramethylpiperidine-1-oxyl, 4-acetamide-2,2,6,6-tetramethylpiperidine-1-oxyl, and bis-(2,2,6,6-tetramethylpiperidine-1-oxyl)-sebacate. For further suppressing generation of residues after development, the radical scavenger is preferably 4-hydroxy-2,2,6,6-tetramethylpiperidine-1-oxyl.

The content of the radical scavenger in the specific photosensitive composition is not particularly limited, and is preferably 0.01 parts by weight or more and 10 parts by weight or less, more preferably 0.05 parts by weight or more and 1 part by weight or less, based on 100 parts by weight of the component (A), from the viewpoint of curability and the balance of the physical properties of the cured product.

As the photosensitive composition which is a material for the rib member 12, not only the specific photosensitive composition, but also a photosensitive composition containing a cationically polymerizable compound other than the component (A) can be used. It is also possible to use a specific photosensitive composition containing the component (A) and a cationically polymerizable compound other than the component (A). Examples of the cationically polymerizable compound other than the component (A) include bisphenol A type epoxy resins, hydrogenated bisphenol A type epoxy resins, novolac phenol type epoxy resins, biphenyl type epoxy resins, dicyclopentadiene type epoxy resins, bisphenol F diglycidyl ether, bisphenol A diglycidyl ether, 2,2′-bis(4-glycidyloxycyclohexyl)propane, vinylcyclohexene dioxide, 2-(3,4-epoxycyclohexyl)-5,5-spiro-(3,4-epoxycyclohexane)-1,3-dioxane, bis(3,4-epoxycyclohexyl)adipate, 1,2-cyclopropanedicarboxylic acid bisglycidyl esters, triglycidyl isocyanurate, monoallyl diglycidyl isocyanurate, diallyl monoglycidyl isocyanurate, 3-ethyl-3-(phenoxymethyl)oxetane, 3′,4′-epoxycyclohexylmethyl 3,4-epoxycyclohexanecarboxylate (“CELLOXIDE (registered trademark) 2021 P” manufactured by DAICEL CORPORATION), and ε-caprolactone-modified 3′,4′-epoxycyclohexylmethyl 3,4-epoxycyclohexanecarboxylate (“CELLOXIDE (registered trademark) 2081” manufactured by DAICEL CORPORATION).

When the component (A) and a cationically polymerizable compound (curable compound) other than the component (A) are used in combination, the amount of the cationically polymerizable compound other than the component (A) is preferably 1 part by weight or more and 10 parts by weight or less, more preferably 3 parts by weight or more and 8 parts by weight or less, based on 100 parts by weight of the component (A) for forming the rib member 12 which is excellent in heat resistance while improving storage stability of the specific photosensitive composition.

### [Preferred Aspects of Ribbed Substrate]

For obtaining an optical semiconductor device which can further suppress generation of optical noise, the ribbed substrate according to the first embodiment preferably satisfies the following condition 1, more preferably satisfies the following condition 2, still more preferably satisfies the following condition 3, and even more preferably satisfies the following condition 4.
Condition 1: The arithmetic mean roughness Ra of the inner peripheral surface of the rib member is 200 nm or more and 900 nm or less, and the value of skewness Ssk of the inner peripheral surface of the rib member is negative.
Condition 2: The condition 1 is satisfied, and the skewness Ssk of the inner peripheral surface of the rib member is −0.80 or more and −0.10 or less.
Condition 3: The condition 2 is satisfied, and the rib member is formed of a cured product of a photosensitive composition having a linear structure and a cyclic structure.
Condition 4: The condition 3 is satisfied, and the photosensitive composition as a material for the rib member contains a polysiloxane compound having the linear structure.

### Second Embodiment: Optical Semiconductor Device

Next, an optical semiconductor device according to a second embodiment of the present invention will be described with reference to the drawings as appropriate. The optical semiconductor device according to the second embodiment is an optical semiconductor device including the ribbed substrate according to the first embodiment (for example, a solid imaging device). In the following description, descriptions of contents overlapping with those of the first embodiment may be omitted.

The optical semiconductor device according to the second embodiment includes the ribbed substrate according to the first embodiment and a semiconductor substrate provided with a light receiving element. A transparent substrate of the ribbed substrate and the semiconductor substrate are laminated with a rib member of the ribbed substrate interposed therebetween. The rib member is provided so as to surround the light receiving element.

The optical semiconductor device according to the second embodiment can suppress generation of optical noise because it includes the ribbed substrate according to the first embodiment.

Hereinafter, as a specific example of the optical semiconductor device according to the second embodiment, an optical semiconductor device (optical semiconductor device 50) further including a wiring substrate and a chip size package type optical semiconductor device (optical semiconductor device 100) will be described with reference to the drawings.

### [Optical Semiconductor Device 50]

FIG. 3 is a sectional view showing the optical semiconductor device 50 which is a specific example of the optical semiconductor device according to the second embodiment. The optical semiconductor device 50 includes the ribbed substrate 10 and the semiconductor substrate 14. As described above, the ribbed substrate 10 includes the transparent substrate 11 and the rib member 12. Alight receiving element 13 is provided on a first surface 14a of the semiconductor substrate 14. The optical semiconductor device 50 further includes a wiring substrate 17 (interposer) bonded to a second surface 14b of the semiconductor substrate 14 (a surface of the semiconductor substrate 14 on a side opposite to the transparent substrate 11 side) with a die bond material 18 interposed therebetween. The term “first surface 14a of the semiconductor substrate 14” means one of two principal surfaces perpendicular to the thickness direction of the semiconductor substrate 14. The term “second surface 14b of the semiconductor substrate 14” means the other one of two principal surfaces perpendicular to the thickness direction of the semiconductor substrate 14. The transparent substrate 11 is disposed so as to face the first surface 14a of the semiconductor substrate 14. The transparent substrate 11 and the semiconductor substrate 14 are laminated with the rib member 12 interposed therebetween. The rib member 12 is provided so as to surround the light receiving element 13.

The semiconductor substrate 14 and the wiring substrate 17 are provided with a semiconductor substrate electrode pad 15 and a wiring substrate electrode pad 16, respectively. The semiconductor substrate electrode pad 15 and the wiring substrate electrode pad 16 are electrically connected through a metallic wire 19. The rib member 12 is disposed between the semiconductor substrate electrode pad 15 and the light receiving element 13, and a peripheral portion of the rib member 12 (a region including a wire 19) is sealed with the sealing resin 20. A solder ball 21 (external connection terminal) is formed on a surface of the wiring substrate 17 on a side opposite to a die bond material 18.

An internal space Z surrounded by the semiconductor substrate 14, the transparent substrate 11, and the rib member 12 may be a sealed space. Here, the rib member 12 functions as a partition wall that prevents ingress of moisture and dust into an effective image region. When ventilation holes are formed in the rib member 12, ingress of foreign matter into the internal space Z can be prevented by forming the rib member 12 in the shape of a maze.

In the ribbed substrate 10, the arithmetic mean roughness Ra of the inner peripheral surface 12a of the rib member 12 is 50 nm or more and 3,000 nm or less. Therefore, in an optical semiconductor device 50 manufactured using the ribbed substrate 10, the generated stray light is diffusely reflected in reflection by the inner peripheral surface 12a of the rib member 12. The diffusely reflected stray light is not so intense that optical noise is generated, and therefore, even if the stray light is incident on the light receiving element 13, the optical semiconductor device 50 enables suppression of generation of optical noise.

Examples of the semiconductor substrate 14 include image sensor substrates. The thickness of the semiconductor substrate 14 is, for example, 50 μm or more and 800 μm or less.

The die bond material 18 is not particularly limited, and is preferably a thermosetting resin such as an epoxy resin or a silicone resin which is not significantly degraded by reflow at a temperature of about 260° C.

The wiring substrate 17 is a multi-layer wiring substrate including a glass epoxy resin base material or the like and metal wiring, and wiring and interlayer connection vias are formed on a surface of the wiring substrate and inside the wiring substrate. On a surface of the wiring substrate 17 on which the semiconductor substrate 14 is installed, the wiring substrate electrode pad 16 for connection to the semiconductor substrate electrode pad 15 on the semiconductor substrate 14 by the wire 19 is provided. The solder ball 21 which is an external connection terminal is formed on a surface of the wiring substrate 17 on a side opposite to the semiconductor substrate 14. The wiring substrate 17 also has a function as a support substrate that suppresses deformation of the semiconductor substrate 14.

The sealing resin 20 is not particularly limited, and a thermosetting resin such as an epoxy resin, an acrylic resin, or a silicone resin is preferable, and an epoxy resin is preferable from the viewpoint of toughness and heat resistance of the resin. From the viewpoint of reducing optical noise such as flares, the sealing resin 20 is preferably colored in black. From the viewpoint of handleability, it is preferable that the sealing resin 20 contains a filler such as silica and has thixotropy before curing.

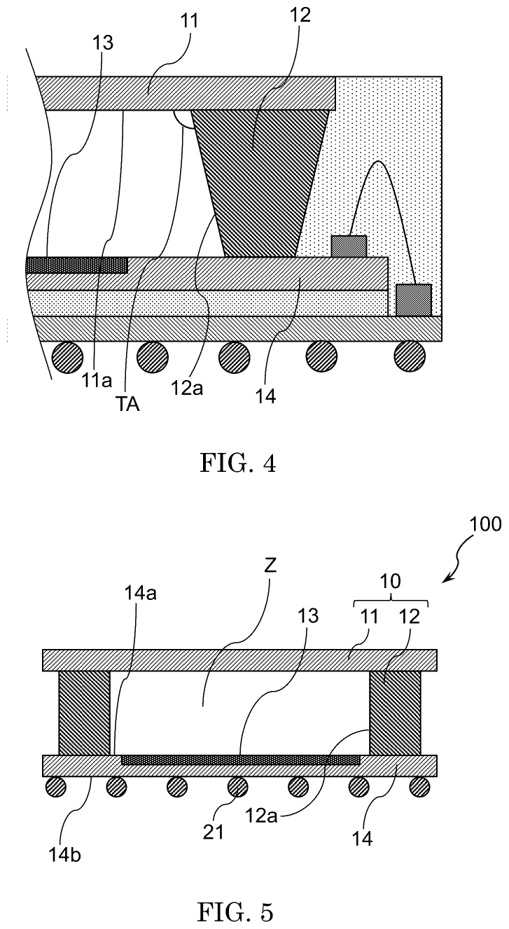

In FIG. 3, the rib member 12 has a rectangular structure in sectional view, but the cross-sectional shape of the rib member 12 is not limited thereto. For example, as shown in FIG. 4, an angle TA formed by a principal surface 11a of the transparent substrate 11 on the semiconductor substrate 14 side and an inner peripheral surface 12a of the rib member 12 may be more than 90°. In the following description, the degree of the angle formed by a principal surface of the transparent substrate on the semiconductor substrate side and the inner peripheral surface of the rib member may be referred to as a “taper angle” (angle TA in FIG. 4).

For obtaining an optical semiconductor device which can further suppress generation of optical noise by inhibiting light incident on the rib member 12 from being reflected to the light receiving element 13, the taper angle is preferably 90° or more, more preferably more than 90°, still more preferably 95° or more, even more preferably 100° or more, and may be 110° or more. For obtaining an optical semiconductor device excellent in reliability by securing a sufficient bonding area between the rib member 12 and the semiconductor substrate 14, the taper angle is preferably 130° or less, more preferably 125° or less, still more preferably 120° or less.

### [Optical Semiconductor Device 100]

Next, as another specific example of the optical semiconductor device according to the second embodiment, the optical semiconductor device 100 of chip size package type (CSP type) will be described with reference to the drawings. In the following description, descriptions of contents overlapping with those of the optical semiconductor device 50 may be omitted.

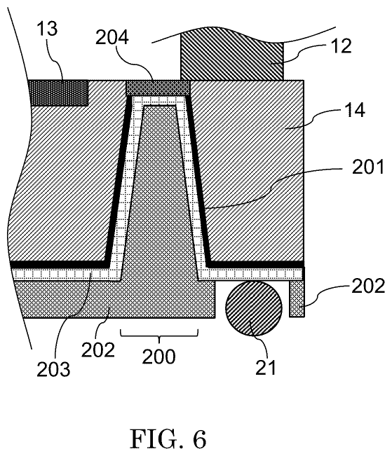

FIG. 5 is a sectional view showing the optical semiconductor device 100. Like the optical semiconductor device 50, the optical semiconductor device 100 includes the ribbed substrate 10, and the semiconductor substrate 14 in which the light receiving element 13 is provided on the first surface 14a. In the optical semiconductor device 100, the transparent substrate 11 and the semiconductor substrate 14 are laminated with the rib member 12 interposed therebetween, and the rib member 12 is provided so as to surround the light receiving element 13 as in the optical semiconductor device 50.

Since the optical semiconductor device 100 is of the CSP type, the width of the optical semiconductor device 100 is substantially equal to the width of the semiconductor substrate 14. The optical semiconductor device 100 does not require sealing with a sealing resin because it does not have a wiring substrate, a wiring substrate electrode pad and a wire that are present in the optical semiconductor device 50. In the optical semiconductor device 100, the second surface 14b of the semiconductor substrate 14 is provided with the ball 21 which is an external connection terminal. The optical semiconductor device 100 has an advantage that the device can be downsized due to the structure of the CSP type. Since optical semiconductor device 100 does not have a wiring substrate, it is necessary that separately, the semiconductor substrate 14 and the solder ball 21 be electrically connected. Hereinafter, an example of a method for electrically connecting the semiconductor substrate 14 and the solder ball 21 will be described, but the method is not limited thereto.

Examples of the method for electrical connection include a method in which a through silicon via 200 is provided as shown in FIG. 6. In the configuration of FIG. 6, an insulating layer 201, a rewiring layer 203 and a solder resist 202 are provided in this order on a surface of the semiconductor substrate 14 on a side opposite to the rib member 12 side. The solder ball 21 is formed in an opening of the solder resist 202 and electrically connected through the rewiring layer 203 to an electrode pad 204 formed on a surface of the semiconductor substrate 14 on the rib member 12 side.

The insulating layer 201 is not particularly limited as long as it is formed of a material having high insulation quality, and examples thereof include silicon oxide films (SiO₂ films), silicon nitride films (SiN films), silicon oxynitride films (SiON films), SiOC films, HSQ (Hydrogen Silsesquioxane) films, and MSQ (Methyl Silsesquioxane) films. Examples of the method for forming the insulating layer 201 include a CVD method and a coating method.

The material for the solder resist 202 is not particularly limited as long as it is formed of a material having heat resistance and insulation quality during mounting, and examples thereof include epoxy resins and acrylic resins. Among them, epoxy resins are preferable from the viewpoint of high heat resistance and insulation quality. Examples of the method for forming the solder resist 202 include photolithography and a screen printing method.

The material of the rewiring layer 203 is not particularly limited as long as it has conductivity, and examples thereof include copper (Cu), aluminum (Al), tungsten (W), gold (Au), titanium (Ti), and nickel (Ni). Examples of the method for forming the rewiring layer 203 include a wet etching method, a dry etching method, and a lift-off method.

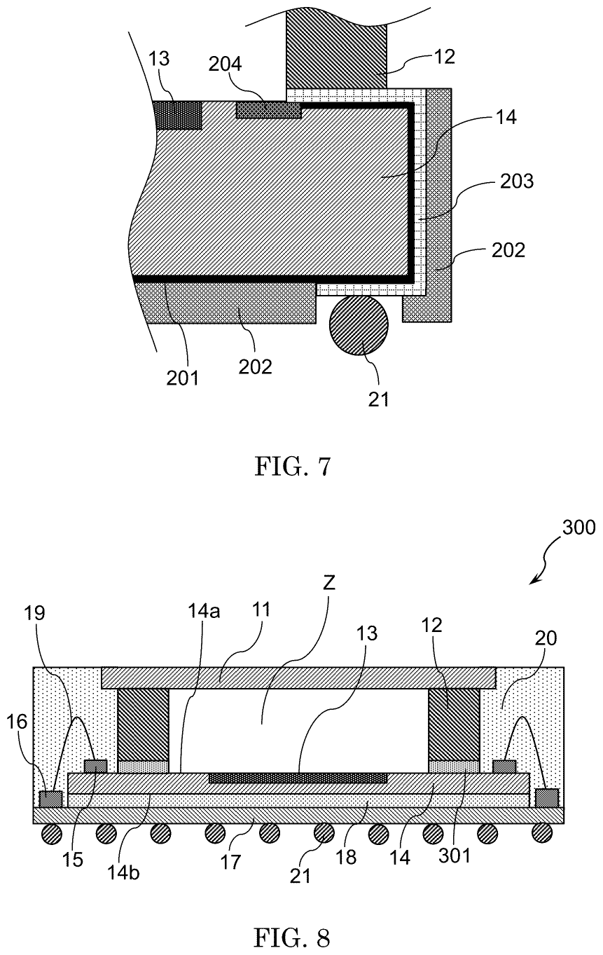

As another example of the method for electrical connection is a method in which as shown in FIG. 7, the rewiring layer 203 is formed along the outer peripheral portion of the semiconductor substrate 14, and the solder ball 21 and the electrode pad 204 are electrically connected through the rewiring layer 203.

For the rest, the optical semiconductor device 100 is the same as described in the above section [Optical semiconductor device 50].

The configuration of the optical semiconductor device according to the second embodiment has been described above with reference to the drawings, but the present invention is not limited to the examples described above. For example, the optical semiconductor device according to the present invention may further include an adhesive layer that bonds the rib member and the semiconductor substrate together. When the optical semiconductor device further includes an adhesive layer that bonds the rib member and the semiconductor substrate together, adhesion between the rib member and the semiconductor substrate is enhanced.

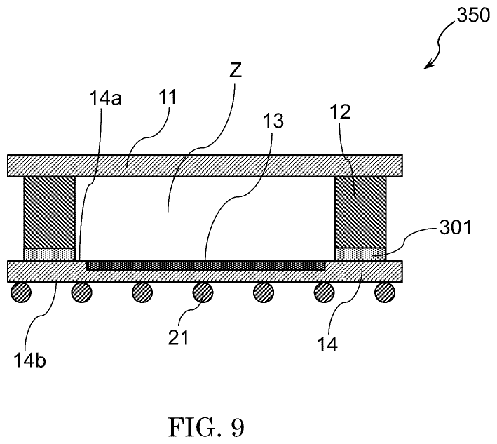

Examples of the optical semiconductor device including an adhesive layer include an optical semiconductor device 300 shown in FIG. 8 and an optical semiconductor device 350 shown in FIG. 9. The optical semiconductor device 300 is the same as the optical semiconductor device 50 except that the rib member 12 and the semiconductor substrate 14 are bonded by the adhesive layer 301. The optical semiconductor device 350 is the same as the optical semiconductor device 100 except that the rib member 12 and the semiconductor substrate 14 are bonded by the adhesive layer 301.

The adhesive layer 301 includes a cured product of an adhesive. Examples of the adhesive as a material for the adhesive layer 301 include thermosetting adhesives (more specifically, epoxy-based adhesives and the like), and ultraviolet-curable adhesives (More specifically, acryl-based adhesives and the like). The term “acryl-based adhesive” means an adhesive containing (meth)acrylic acid or a derivative thereof (more specifically, (meth)acrylic acid ester or the like) or a polymer of (meth)acrylic acid or a derivative thereof as a main component.

For obtaining an optical semiconductor device further excellent in adhesiveness between substrates, the adhesive as a material for the adhesive layer 301 is preferably an epoxy-based adhesive. When an epoxy-based adhesive is used as the adhesive as a material for the adhesive layer 301, the main agent of the epoxy-based adhesive is preferably an aromatic epoxy compound having two or more epoxy groups, more preferably a bisphenol-based diglycidyl ether (more specifically, bisphenol A diglycidyl ether, bisphenol F diglycidyl ether, bisphenol S diglycidyl ether, or the like), still more preferably bisphenol A diglycidyl ether for obtaining an optical semiconductor device further excellent in adhesiveness between substrates.

When an epoxy-based adhesive is used as the adhesive as a material for the adhesive layer 301, the curing agent for the epoxy-based adhesive is preferably an imidazole-based curing agent for obtaining an optical semiconductor device further excellent in adhesiveness between substrates.

For obtaining an optical semiconductor device further excellent in adhesiveness between substrates, the adhesive as a material for the adhesive layer 301 is preferably an epoxy-based adhesive containing bisphenol-based diglycidyl ether as a main agent and an imidazole-based curing agent as a curing agent, more preferably an epoxy-based adhesive containing bisphenol A diglycidyl ether as a main agent and an imidazole-based curing agent as a curing agent. Here, the weight ratio of the main agent to the curing agent (main agent/curing agent) in the epoxy-based adhesive is, for example, 100/10 or more and 100/1 or less.

For obtaining an optical semiconductor device which is excellent in adhesiveness between substrates and also excellent in reliability evaluated in a thermal shock test, the height (thickness) of the adhesive layer 301 is preferably 0.01 μm or more and 200 μm or less, more preferably 0.1 μm or more and 100 μm or less, still more preferably 1 μm or more and 50 μm or less. The width of the adhesive layer 301 can be appropriately changed according to the width of the rib member 12, and is, for example, 10 μm or more and 500 μm or less, preferably 10 μm or more and 300 μm or less, more preferably 20 μm or more and 250 μm or less. For obtaining an optical semiconductor device further excellent in reliability evaluated in a thermal shock test, the width of the adhesive layer 301 when the width of the rib member 12 is defined as 100% is preferably 70% or more, more preferably 80% or more, still more preferably 90% or more, and may be 100% or more, 110% or more, or 120% or more.

### [Method for Manufacturing Optical Semiconductor Device]

Next, a suitable method for manufacturing an optical semiconductor device according to the second embodiment of the present invention will be described with reference to the drawings as appropriate.

Hereinafter, as a suitable method for manufacturing an optical semiconductor device according to the second embodiment, an example of a method for manufacturing an optical semiconductor device 50 shown in FIG. 3 (hereinafter, sometimes referred to as a “manufacturing method M1”) and an example of a method for manufacturing an optical semiconductor device 100 shown in FIG. 5 (hereinafter, sometimes referred to as a “manufacturing method M2”) will be each described with reference to the drawings.

### (Manufacturing Method M1)

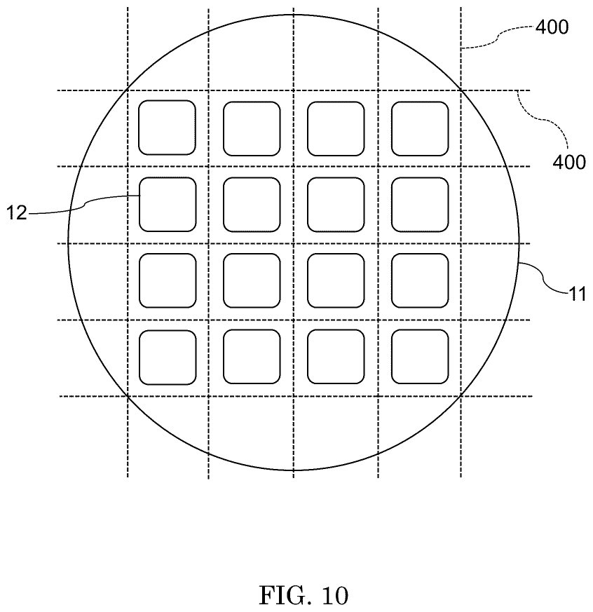

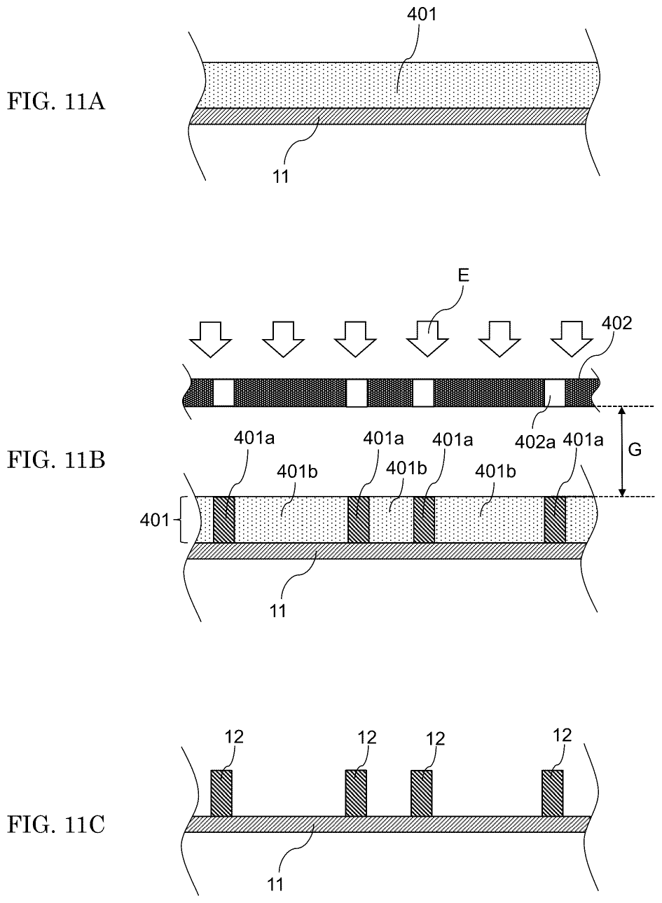

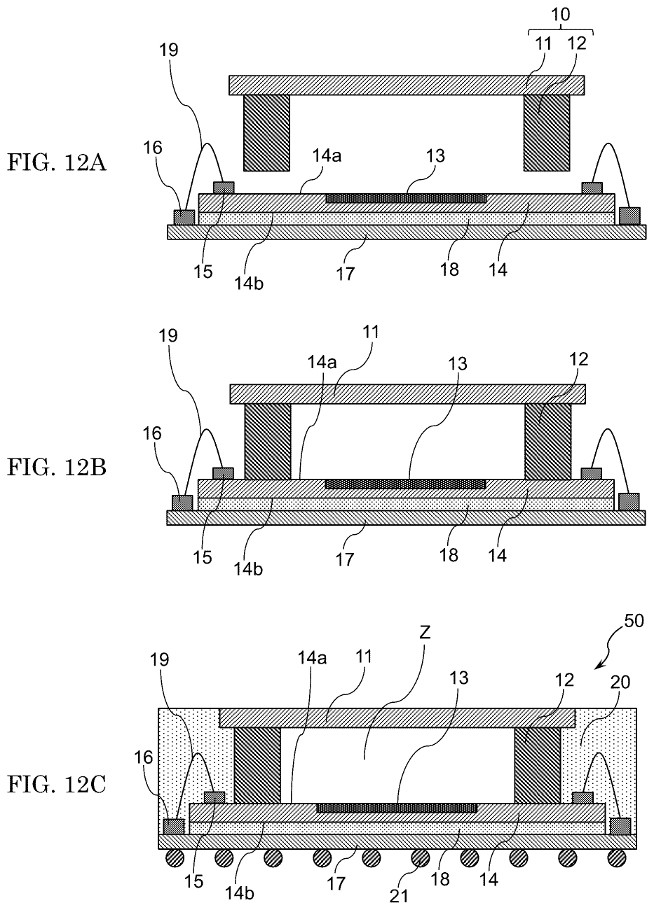

First, the manufacturing method M1 will be described with reference to FIGS. 10 to 12. FIG. 10 is a plan view showing a transparent substrate after formation of a rib member (large-sized transparent substrate) in the manufacture of the optical semiconductor device by the manufacturing method M1. FIGS. 11A to 11C and 12A to 12C are step-by-step sectional views showing manufacture of an optical semiconductor device by the manufacturing method M1.

In the manufacturing method M1, first, the rib member 12 in a semi-cured state is formed on a large-sized transparent substrate 11 in a state of being patterned such that a large number of quadrangle-cylindrical shapes are arranged (FIG. 10). Hereinafter, the rib member in a semi-cured state is sometimes referred to as a “semi-cured rib member.” After the semi-cured rib member 12 is formed on the transparent substrate 11, the transparent substrate 11 is diced along a division line 400 of FIG. 10 to obtain a singulated transparent substrate 11 on which the semi-cured rib member 12 is formed. In dicing, for example, the large-sized transparent substrate 11 is bonded to a dicing tape (not shown) to be fixed, and is cut with a dicing blade (not shown). Here, a surface of the transparent substrate 11 on a side opposite to a surface on which the semi-cured rib member 12 is formed may be bonded to the dicing tape, or the surface on which semi-cured rib member 12 is formed may be bonded to the dicing tape.

In the step of forming the semi-cured rib member 12 on the large-sized transparent substrate 11, for example, a film formed of a photosensitive composition (specifically, a coating film formed of a photosensitive composition after heating) is patterned in a semi-cured state by photolithography. The photolithography enables formation of a large number of semi-cured rib member 12 excellent in dimensional accuracy.

A method for forming the semi-cured rib member 12 by photolithography will be described with reference to FIGS. 11A to 11C. First, a photosensitive composition is applied onto the large-sized transparent substrate 11 to form a film (coating film) formed of the photosensitive composition. The method for application here is not particularly limited, and for example, a general application method such as a spin coating method, or a slit coating method can be used. Subsequently, the coating film is heated to remove the solvent in the coating film, so that a thin film 401 (coating film after heating) is formed on the transparent substrate 11 (FIG. 11A). The temperature for heating the coating film can be appropriately set, and is preferably 60° C. or higher and 200° C. or lower.

Subsequently, a photomask 402 having a light-transmitting region 402a formed at a predetermined position is disposed on the thin film 401, and the thin film 401 is irradiated with an active energy ray E (FIG. 11B). In this way, only the thin film 401 (exposed portion 401a) located below the light-transmitting region 402a is exposed, and undergoes a photocuring reaction. The integrated exposure amount during exposure is not particularly limited, and is preferably 1 mJ/cm² or more and 20,000 mJ/cm² or less, more preferably 10 mJ/cm² or more and 10,000 mJ/cm² or less. The time of irradiation of the thin film 401 with the active energy ray E is preferably 1 second or more and 600 seconds or less, more preferably 1 second or more and 150 seconds or less.

After the exposure, a curing reaction may be allowed to proceed while the semi-cures state of the thin film 401 is maintained by performing baking at a predetermined temperature if necessary.

Subsequently, the exposed thin film 401 is developed. The method for developing the thin film 401 is not particularly limited. For example, an alkaline developer is brought into contact with the thin film 401 by an immersion method or a spray method to dissolve and remove a non-exposed portion 401b, thereby forming the patterned semi-cured rib member 12 on the transparent substrate 11 (FIG. 11C). The alkaline developer is not particularly limited, and may be one that is commonly used. Specific examples of the alkaline developer include organic alkali aqueous solutions such as a tetramethylammonium hydroxide (TMAH) aqueous solution or a choline aqueous solution; and inorganic alkali aqueous solutions such as a potassium hydroxide aqueous solution, a sodium hydroxide aqueous solution, a potassium carbonate aqueous solution, a sodium carbonate aqueous solution, and a lithium carbonate aqueous solution. From the viewpoint of increasing the contrast between the exposed portion 401a and the non-exposed portion 401b, the alkali concentration is preferably 25 wt % or less, more preferably 10 wt % or less, still more preferably 5 wt % or less. For the purpose of, for example, adjusting the dissolution rate, an alcohol or a surfactant may be blended in the alkaline developer. The thin film 401 may be washed with water after the thin film 401 is brought into contact with the alkaline developer. When the thin film 401 is washed with water, it is preferable to remove moisture on the surface of the thin film 401 with compressed air after washing with water.

As the developer for the thin film 401, an organic solvent developer may be used instead of an alkali developer. Any organic solvent developer may be used as long as it can remove the non-exposed portion 401b from the transparent substrate 11 while allowing the patterned exposed portion 401a to remain on the transparent substrate 11. Examples of the organic solvent developer include acetone, ethyl acetate, alkoxy ethanols having an alkoxy group having 1 to 4 carbon atoms, ethyl alcohol, isopropyl alcohol, butyl alcohol, diethylene glycol monomethyl ether, diethylene glycol monoethyl ether, diethylene glycol monobutyl ether, 1,1,1-trichloroethane, N-methyl-2-pyrrolidone, N,N-dimethylformamide, cyclohexanone, methyl isobutyl ketone, γ-butyrolactone, triethylene glycol dimethyl ether, and propylene glycol 1-monomethyl ether 2-acetate. To the organic solvent developer, a surfactant, an antifoaming agent, and the like may be added in a small amount, and water may be added in an amount of 1 vol % or more and 30 vol % or less for the purpose of preventing ignition. The method for removing the non-exposed portion 401b from the transparent substrate 11 with the organic solvent developer is not particularly limited, and examples thereof include a method in which the organic solvent developer is brought into contact with the thin film 401 by an immersion method, a spray method or a paddle method to dissolve and remove the non-exposed portion 401b.

When the thin film 401 formed of a photoradically polymerizable photosensitive composition is exposed, radical polymerization of the non-exposed portion 401b adjacent to the exposed portion 401a is likely to be suppressed due to oxygen inhibition in a region of the exposed portion 401a, which is relatively close to the photomask 402. On the other hand, when the thin film 401 formed of a photoradically polymerizable photosensitive composition is exposed, a region of the exposed portion 401a, which is relatively far from the photomask 402, is hardly influenced by oxygen inhibition, and therefore, in this region, radical polymerization of the non-exposed portion 401b adjacent to the exposed portion 401a is unlikely to be suppressed. For this reason, when the thin film 401 formed of a photoradically polymerizable photosensitive composition is patterned by photolithography, the width of the semi-cured rib member 12 after development tends to be larger on the transparent substrate 11 side than on a side opposite to the transparent substrate 11 (surface layer side). Thus, when the thin film 401 formed of a photoradically polymerizable photosensitive composition is patterned by photolithography, the taper angle can be made larger than 90°. The taper angle can be adjusted by, for example, changing at least one of the interval G between the thin film 401 and the photomask 402 (see FIG. 11B) and the integrated exposure amount. The interval G is, for example, 50 μm or more and 2,000 μm or less.

For easily adjusting the taper angle to fall within a range above 90°, it is preferable that the photosensitive composition applied onto the transparent substrate 11 contains the component (A), the component (B), and the component (C), with the component (B) being a photoradical polymerization initiator.

Next, the step of laminating the singulated ribbed substrate 10 on which the semi-cured rib member 12 is formed and the semiconductor substrate 14 (lamination step) will be described. First, a semiconductor substrate laminated product is prepared. As the semiconductor substrate laminated product, a laminated product can be used in which as shown in FIG. 12A, the semiconductor substrate 14 provided with the light receiving element 13 and the wiring substrate 17 are bonded with the die bond material 18 interposed therebetween, and the semiconductor substrate electrode pad 15 and a wiring substrate electrode pad 16 are electrically connected through the wire 19.

As shown in FIG. 12A, the transparent substrate 11 on which the semi-cured rib member 12 is formed and the semiconductor substrate laminated product are disposed in such a manner that a principal surface of the transparent substrate 11 on which the semi-cured rib member 12 is formed and a principal surface of the semiconductor substrate 14 on which the light receiving element 13 is provided face each other, followed by lamination of the transparent substrate 11 and the semiconductor substrate laminated product (FIG. 12B). In the lamination step, the semi-cured rib member 12 is disposed on the periphery of the light receiving element 13.

Next, the step of curing the semi-cured rib member 12 (curing step) will be described. First, the laminate obtained in the lamination step is heated while, for example, a load is applied thereto, so that the transparent substrate 11 and the semiconductor substrate laminated product are thermocompression-bonded. The heating temperature here is, for example, 80° C. or higher and 200° C. or lower. The laminate after thermocompression bonding is heated at a temperature of, for example, 100° C. or higher and 300° C. or lower. Through the curing step described above, the semi-cured rib member 12 is cured, and the transparent substrate 11 and the semiconductor substrate 14 are bonded with the rib member 12 interposed therebetween. Subsequently, as shown in FIG. 12C, the peripheral portion of the rib member 12 (a region including the wire 19) is sealed with the sealing resin 20, and the solder ball 21 is formed on a surface of the wiring substrate 17 on a side opposite to the semiconductor substrate 14 to obtain the optical semiconductor device 50.

In the manufacturing method M1, the semi-cured rib member 12 is formed on the transparent substrate 11, but the semi-cured rib member 12 may be formed on the semiconductor substrate 14, with the lamination step and the curing step being carried out in the same procedure as described above.

### (Manufacturing Method M2)

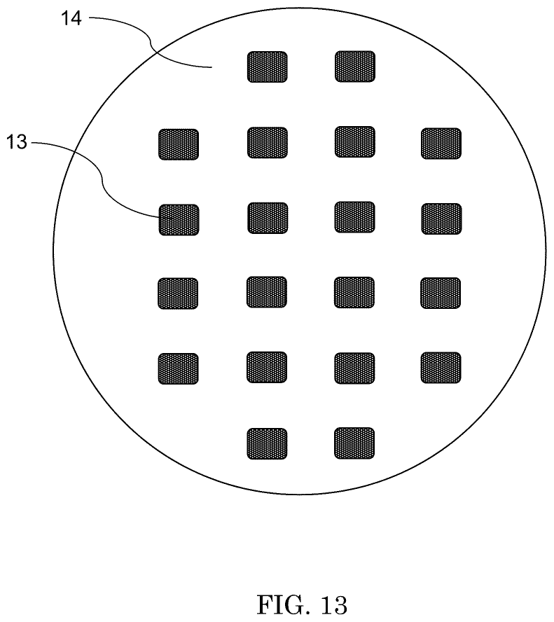

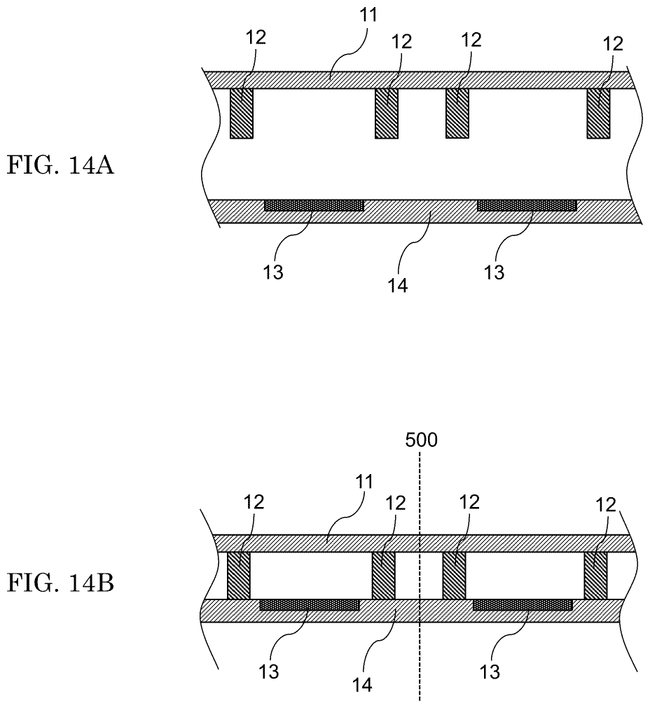

Next, the manufacturing method M2 will be described with reference to FIGS. 13 and 14. FIG. 13 is a plan view showing a semiconductor substrate after formation of a light receiving element in manufacturing of the optical semiconductor device by the manufacturing method M2. FIGS. 14A to 14B are step-by-step sectional views showing the lamination step in the manufacturing method M2.

In the manufacturing method M2, first, the semi-cured rib member 12 is formed in the same manner as in the manufacturing method M1. Specifically, in the same manner as in the manufacturing method M1, the semi-cured rib member 12 is formed on a large-sized transparent substrate 11 in a state of being patterned such that a large number of quadrangle-cylindrical shapes are arranged (see FIG. 10). Separately, the large-sized semiconductor substrate 14 (see FIG. 13) provided with a plurality of light receiving elements 13 is provided.

Next, the lamination step will be described. As shown in FIG. 14A, the large-sized transparent substrate 11 on which the semi-cured rib member 12 is formed and the large-sized semiconductor substrate 14 provided with a plurality of light receiving elements 13 are disposed in such a manner that a principal surface of the transparent substrate 11 on which the semi-cured rib member 12 is formed and a principal surface of the semiconductor substrate 14 on which the light receiving element 13 is provided face each other, followed by lamination of the transparent substrate 11 and the semiconductor substrate 14 (FIG. 14B). In the lamination step, the semi-cured rib member 12 is disposed on the periphery of the light receiving element 13.

Next, the curing step will be described. First, the laminate obtained in the lamination step is heated while, for example, a load is applied thereto, so that the transparent substrate 11 and the semiconductor substrate 14 are thermocompression-bonded. The heating temperature here is, for example, 80° C. or higher and 200° C. or lower. The laminate after thermocompression bonding is heated at a temperature of, for example, 100° C. or higher and 300° C. or lower. Through the curing step described above, the semi-cured rib member 12 is cured, and the transparent substrate 11 and the semiconductor substrate 14 are bonded with the rib member 12 interposed therebetween.

Subsequently, dicing is performed along a division line 500 in FIG. 14B, and the solder ball 21 is formed on a surface of the semiconductor substrate 14 on a side opposite to the transparent substrate 11 to obtain the optical semiconductor device 100 shown in FIG. 5.

In the manufacturing method M2, the semi-cured rib member 12 is formed on the transparent substrate 11, but the semi-cured rib member 12 may be formed on the semiconductor substrate 14, with the lamination step and the curing step being carried out in the same procedure as described above. Alternatively, using the singulated semiconductor substrate 14 and the singulated transparent substrate 11, the lamination step and the curing step may be carried out in the same procedure as described above.

While a suitable method for manufacturing an optical semiconductor device according to the second embodiment has been described above, the method for manufacturing the optical semiconductor device according to the second embodiment is not limited to the manufacturing method described above. For example, in the manufacturing methods M1 and M2, the large-sized transparent substrate 11 on which the semi-cured rib member 12 is formed and the semiconductor substrate 14 are laminated, and the semi-cured rib member 12 is then cured. Alternatively, the semi-cured rib member 12 is cured before the lamination step, and the cured rib member 12 and the semiconductor substrate 14 are bonded with an adhesive interposed therebetween. By this method, for example, the optical semiconductor device 300 shown in FIG. 8 or the optical semiconductor device 350 shown in FIG. 9 is obtained. The heating temperature in curing of the semi-cured rib member 12 before the lamination step is preferably 80° C. or higher and 350° C. or lower, more preferably 150° C. or higher and 250° C. or lower. After the semi-cured rib member 12 is cured, the reaction rate of the curable compound in the rib member 12 before the cured rib member 12 and the semiconductor substrate 14 are bonded to each other is preferably 90% or more. The method for measuring the reaction ratio is identical or similar to that in examples described later. After the semi-cured rib member 12 is cured, the content of the alkali component in the rib member 12 before the cured rib member 12 and the semiconductor substrate 14 are bonded to each other is preferably 1,000 ppm or less, more preferably 100 ppm or less.

### EXAMPLE

Hereinafter, the present invention will be described in more detail by way of examples, but the present invention is not limited to these examples.

### <Synthesis of Curable Compound>

Hereinafter, methods for synthesis of curable compounds P1 to P6 will be described. The weight average molecular weights of curable compounds P1 and P2 and linear polysiloxane compounds LP1 to LP4 were calculated in terms of standard polystyrene from a chromatogram obtained by measuring the weight average molecular weight at a flow rate of 1.0 mL/min using “HLC-8420GPC” (Column: Shodex GPC KD-806 M (2 columns) and TSKgel SuperAWM-H (2 columns)) manufactured by Tosoh Corporation, and N,N-dimethylformamide as a solvent.

### [Synthesis of Curable Compound P1]

95.5 μL of a xylene solution of a platinum vinyl siloxane complex (“Pt-VTSC-3X” manufactured by Umicore Precious Metals Japan Co., Ltd., solution with a platinum content of 3 wt %) was added to a mixture of 40 g of diallyl isocyanurate, 4.8 g of diallyl monomethyl isocyanurate, 2.2 g of a linear polysiloxane compound LP1 and 240 g of 1,4-dioxane to obtain a solution S1. In the linear polysiloxane compound LP1 is polydimethylsiloxane having a vinyl group at both ends (“DMS-V31” manufactured by Gelest, Inc., weight average molecular weight: 28,000). Meanwhile, 58.8 g of 1,3,5,7-tetrahydrogen-1,3,5,7-tetramethylcyclotetrasiloxane was dissolved in 117.6 g of toluene to obtain a solution S2.

In a nitrogen atmosphere containing 3 vol % of oxygen, the solution S1 was added dropwise to the solution S2 over 3 hours with the solution S2 heated at a temperature of 105° C. After completion of the dropwise addition, the mixture was stirred for 30 minutes while being maintained at a temperature of 105° C., thereby obtaining a solution S3. The reaction ratio of the alkenyl group of the compound contained in the obtained solution S3 was measured by ¹H-NMR, and the result showed that the reaction ratio was 95% or more.

Meanwhile, 41.17 g of 1-vinyl-3,4-epoxycyclohexane was dissolved in 41.17 g of toluene to obtain a solution S4.

In a nitrogen atmosphere containing 3 vol % of oxygen, the solution S4 was added dropwise to the solution S3 over 1 hour with the solution S3 heated at a temperature of 105° C. After completion of the dropwise addition, the mixture was stirred for 30 minutes while being maintained at a temperature of 105° C., thereby obtaining a solution S5. The reaction ratio of the alkenyl group of the compound contained in the obtained solution S5 was measured by ¹H-NMR, and the result showed that the reaction ratio was 95% or more.

Subsequently, the solution S5 was cooled, and the solvent (toluene, xylene and 1,4-dioxane) was then distilled off from the solution S5 under reduced pressure to obtain a solid. Propylene glycol 1-monomethyl ether 2-acetate (hereinafter, referred to as “PGMEA”) was added to the obtained solid to obtain a solution SP1 containing the curable compound P1 (concentration of the curable compound P1: 70 wt %). The curable compound P1 was a polysiloxane compound having a weight average molecular weight of 18,200. The curable compound P1 had a plurality of cationically polymerizable groups (specifically, alicyclic epoxy groups), a plurality of alkali-soluble groups (specifically, X2 groups) and a linear structure part (a linear structure part derived from the linear polysiloxane compound LP1) in one molecule, and a cyclic polysiloxane structure in the main chain.

### [Synthesis of Curable Compound P2]

A solution SP2 containing a curable compound P2 (a polysiloxane compound having a weight average molecular weight of 16,950) (concentration of curable compound P2: 70 wt %) was produced in the same manner as in synthesis of the curable compound P1 except that 2.2 g of a linear polysiloxane compound LP2 was used instead of 2.2 g of the linear polysiloxane compound LP1. The linear polysiloxane compound LP2 was a compound represented by the following general formula Y In the linear polysiloxane compound LP2, the substance amount ratio of (Ratio of r, s, and t) of each structural unit was r:s:t=30:0:70, and the weight average molecular weight was 26,000.

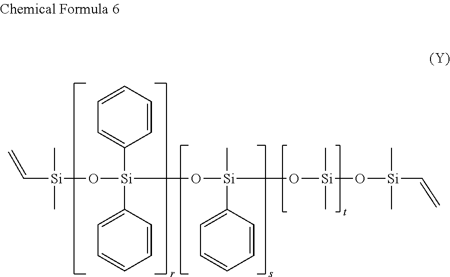

The curable compound P2 had a plurality of cationically polymerizable groups (specifically, alicyclic epoxy groups), a plurality of alkali-soluble groups (specifically, X2 groups) and a linear structure part (a linear structure part derived from the linear polysiloxane compound LP2) in one molecule, and a cyclic polysiloxane structure in the main chain.

### [Synthesis of Curable Compound P3]

A solution SP3 containing a curable compound P3 (concentration of curable compound P3: 70 wt %) was produced in the same manner as in synthesis of the curable compound P1 except that 2.2 g of a linear polysiloxane compound LP3 was used instead of 2.2 g of the linear polysiloxane compound LP1. The linear polysiloxane compound LP3 was a compound represented by the general formula Y In the linear polysiloxane compound LP3, the substance amount ratio of (Ratio of r, s and t) of each structural unit was r:s:t=0:100:0, and the weight average molecular weight was 2,300.

The curable compound P3 had a plurality of cationically polymerizable groups (specifically, alicyclic epoxy groups), a plurality of alkali-soluble groups (specifically, X2 groups) and a linear structure part (a linear structure part derived from the linear polysiloxane compound LP3) in one molecule, and a cyclic polysiloxane structure in the main chain.

### [Synthesis of Curable Compound P4]

A solution SP4 containing a curable compound P4 (concentration of curable compound P4: 70 wt %) was produced in the same manner as in synthesis of the curable compound P1 except that 2.2 g of a linear polysiloxane compound LP4 was used instead of 2.2 g of the linear polysiloxane compound LP1. The linear polysiloxane compound LP4 was a compound represented by the general formula (Y). In the linear polysiloxane compound LP4, the substance amount ratio of (Ratio of r, s, and t) of each structural unit was r:s:t=0:100:0, and the weight average molecular weight was 10,000.

The curable compound P4 had a plurality of cationically polymerizable groups (specifically, alicyclic epoxy groups), a plurality of alkali-soluble groups (specifically, X2 groups) and a linear structure part (a linear structure part derived from the linear polysiloxane compound LP4) in one molecule, and a cyclic polysiloxane structure in the main chain.

### [Synthesis of Curable Compound P5]

A solution SP5 containing a curable compound P5 (concentration of curable compound P5: 70 wt %) was produced in the same manner as in synthesis of the curable compound P1 except that 2.2 g of the linear polysiloxane compound LP1 was not used. The curable compound P5 had a plurality of cationically polymerizable groups (specifically, alicyclic epoxy groups) and a plurality of alkali-soluble groups (specifically, X2 groups) in one molecule, and a cyclic polysiloxane structure in the main chain.

### [Synthesis of Curable Compound P6]

A solution SP6 containing a curable compound P6 (concentration of curable compound P6: 70 wt %) was produced in the same manner as in synthesis of the curable compound P1 except that a solution obtained by dissolving 20.6 g of 1-vinyl-3,4-epoxycyclohexane and 18.6 g of an allyl acrylate in 39.2 g of toluene was used as the solution S4. The curable compound P6 had a plurality of cationically polymerizable groups (specifically, alicyclic epoxy groups), a plurality of alkali-soluble groups (specifically, X2 groups), a linear structure part (a linear structure part derived from the linear polysiloxane compound LP1) and a plurality of radically polymerizable groups (specifically, acryloyl groups) in one molecule, and a cyclic polysiloxane structure in the main chain.

### <Preparation of Other Materials>

As materials for photosensitive compositions, the following materials were prepared in addition to the solutions SP1 to SP6 and PGMEA.
Linear polysiloxane compound LP1 (“DMS-V31” manufactured by Gelest Inc., weight average molecular weight: 28,000, hereinafter referred to as “LP1”)
3′,4′-Epoxycyclohexylmethyl 3,4-epoxycyclohexanecarboxylate (“CELLOXIDE (registered trademark) 2021P” manufactured by DAICEL CORPORATION, hereinafter referred to as “2021P”) as a curable compound
Ditrimethylolpropane tetraacrylate (“AD-TMP” manufactured by Shin-Nakamura Chemical Co., Ltd., compound having four acryloyl groups in one molecule, hereinafter referred to as “AD-TMP”)
Caprolactone-modified tris-(2-acryloxyethyl) isocyanurate (“A-9300-1CL” manufactured by Shin-Nakamura Chemical Co., Ltd., compound having three acryloyl groups in one molecule, hereinafter referred to as “A-9300”)
Silica particles (“KYKLOS (registered trademark) MSR-04” manufactured by Tatsumori Ltd., average particle diameter: 4.1 μm) as a filler
An aromatic sulfonium salt-based compound (“CPI-210S” manufactured by San-Apro Ltd, hereinafter referred to as “CPI-210S”) as a photocationic polymerization initiator
A benzophenone-based compound as photoradical polymerization initiator (“Omnirad (registered trademark) 651” manufactured by IGM Resins, hereinafter referred to as “651”)
4-Hydroxy-2,2,6,6-tetramethylpiperidine-1-oxyl (manufactured by Evonik Industries AG, hereinafter referred to as “H-TEMPO”) as a radical scavenger

### <Preparation of Photosensitive Composition>

The materials shown in Tables 1 and 2 were blended in the blending amounts shown in Tables 1 and 2, thereby obtaining photosensitive compositions PS1 to PS13 used in examples and comparative examples. The curable compounds P1 and P6 were blended in the form of the solutions SP1 to SP6, respectively. In Tables 1 and 2, the blending amount of PGMEA also includes the amount of PGMEA in the solution SP1, SP2, SP3, SP4, SP5 or SP6. In Tables 1 and 2, the terms “P1” to “P6” mean the curable compounds P1 to P6, respectively. In Tables 1 and 2, “-” means that the relevant material was not blended.

TABLE 1

| Photosensitive composition | | PS1 | PS2 | PS3 | PS4 | PS5 | PS6 | PS7 |
|---|---|---|---|---|---|---|---|---|
| Blending amount of each | P1 | 100 | — | — | — | — | 100 | 100 |
| material (unit: parts by | P2 | — | 100 | — | — | — | — | — |
| weight) | P3 | — | — | 100 | — | — | — | — |
| | P4 | — | — | — | 100 | — | — | — |
| | P5 | — | — | — | — | 100 | — | — |
| | P6 | — | — | — | — | — | — | — |
| | LP1 | — | — | — | — | 2.5 | 2.5 | 5 |
| | 2021P | 5 | 5 | 5 | 5 | 5 | — | — |
| | AD-TMP | — | — | — | — | — | — | — |
| | A-9300 | — | — | — | — | — | — | — |
| | Silica particles | — | — | — | — | — | — | — |
| | CPI-210S | 1.5 | 1.5 | 1.5 | 1.5 | 1.5 | 1.5 | 1.5 |
| | 651 | — | — | — | — | — | — | — |
| | H-TEMPO | — | — | — | — | — | — | — |
| | PGMEA | 6.5 | 6.5 | 6.5 | 6.5 | 6.5 | 6.5 | 6.5 |

TABLE 2

| Photosensitive composition | | PS8 | PS9 | PS10 | PS11 | PS12 | PS13 |
|---|---|---|---|---|---|---|---|
| Blending amount of each | P1 | — | 100 | 100 | — | — | — |
| material (unit: parts by | P2 | — | — | — | 100 | — | — |
| weight) | P3 | — | — | — | — | — | — |
| | P4 | — | — | — | — | — | — |
| | P5 | — | — | — | — | 100 | 100 |
| | P6 | 100 | — | — | — | — | — |
| | LP1 | — | — | — | — | — | — |
| | 2021P | — | — | — | — | 5 | — |
| | AD-TMP | 30 | 30 | — | 30 | — | 30 |
| | A-9300 | — | — | 30 | — | — | — |
| | Silica particles | — | — | — | — | — | 10 |
| | CPI-210S | — | — | — | — | 1.5 | — |
| | 651 | 1 | 1 | 1 | 1 | — | 1 |
| | H-TEMPO | 0.1 | 0.1 | 0.1 | 0.1 | — | 0.1 |
| | PGMEA | 6.5 | 6.5 | 6.5 | 6.5 | 6.5 | 6.5 |

### <Production of Ribbed Substrate and Optical Semiconductor Device>

Hereinafter, methods for producing ribbed substrates in Examples 1 to 15 and Comparative Examples 1 to 3 and methods for producing optical semiconductor devices in Examples 1 to 15 and Comparative Examples 1 to 3 will be described.

### Example 1

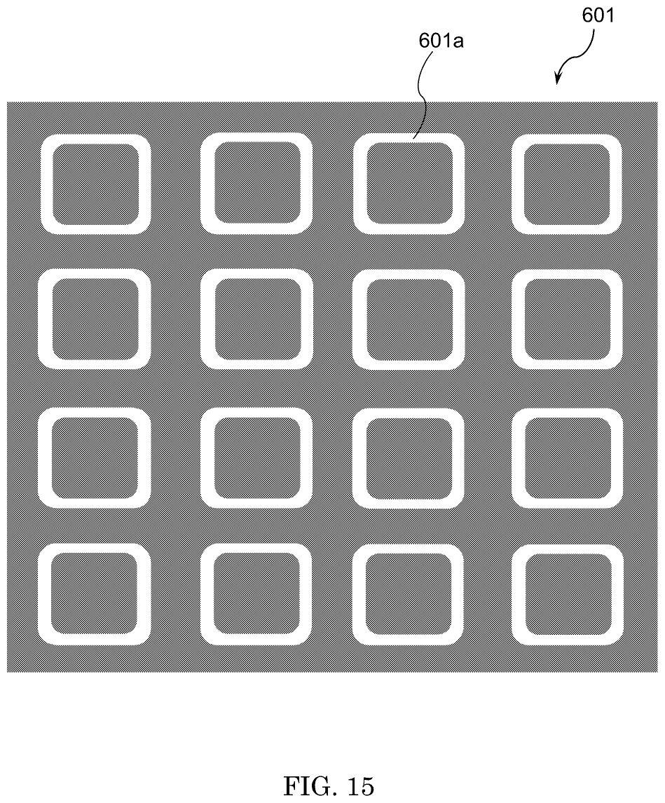

A photosensitive composition PS1 was applied onto a glass substrate as a transparent substrate by a spin coater to obtain a first laminate in which a coating film formed of the photosensitive composition PS1 is formed on a glass substrate. Subsequently, the first laminate was heated for 10 minutes on a hot plate heated to a temperature of 120° C. Subsequently, through a photomask 601 shown in FIG. 15 (the photomask 601 having a light-transmitting region 601a having a width of 200 am), the coating film of the heated first laminate was irradiated with light under the condition of an integrated exposure amount of 2,000 mJ/cm² using a manual exposure machine (“MA-1300” manufactured by Japan Science Engineering Co., Ltd., lamp: high-pressure mercury lamp). In this way, the coating film was exposed (specifically, soft contact exposure).

The exposed first laminate was allowed to stand in an atmosphere at a temperature of 25° C. for 1 minute, and then immersed in a TMAH aqueous solution (concentration of TMAH: 2.38 wt %) as an alkaline developer for 60 seconds. Subsequently, the first laminate immersed in the alkaline developer was washed with water for 30 seconds, and moisture on the surface was removed with compressed air. In this way, the coating film on the glass substrate was patterned in a semi-cured state to obtain a glass substrate provided with a plurality of rib members having a quadrangle-cylindrical structure. The thickness of the rib member is 50 μm. Hereinafter, the glass substrate provided with a plurality of rib members having a quadrangle-cylindrical structure is referred to as a “sample 1.”

Subsequently, the sample 1 was cut between the rib members with a dicing blade to obtain ribbed substrates (singulated sample 1) of Example 1.

Next, the obtained ribbed substrate and the semiconductor substrate laminated product were laminated to form a second laminate. Here, the ribbed substrate and the semiconductor substrate laminated product were laminated such that a principal surface of the semiconductor substrate on which the light receiving element is provided and a principal surface of the ribbed substrate on which the rib member is provided faced each other. As the semiconductor substrate laminated product, a semiconductor substrate laminated product was used in which a semiconductor substrate provided with a light receiving element and a wiring substrate are bonded with a die bond material interposed therebetween, and an electrode pad on the semiconductor substrate and an electrode pad on the wiring substrate are electrically connected through a metallic wire. Subsequently, a load of 500 g was applied to the second laminate on a hot plate at a temperature of 120° C. for 30 seconds to thermocompression-bond the semiconductor substrate and the glass substrate with the rib member interposed therebetween. Subsequently, the laminate after thermocompression bonding was heated in an oven at a temperature of 200° C. for 2 hours to cure the rib member. Subsequently, the peripheral portion of the rib member (a region including the wire) was sealed with a sealing resin, and a solder ball was formed on a surface of the wiring substrate on a side opposite to the semiconductor substrate side to obtain an optical semiconductor device of Example 1. The optical semiconductor device of Example 1 had a structure shown in FIG. 3. In the optical semiconductor device of Example 1, the thickness of the rib member was 50 μm.

### Example 2 to 11, Example 15 and Comparative Example 1

Ribbed substrates of Examples 2 to 11 and 15 and Comparative Example 1 and optical semiconductor devices of Examples 2 to 11 and 15 and Comparative Example 1 were each produced in the same manner as in Example 1 except that the types of photosensitive compositions were as shown in Tables 3 to 5 below.

### Example 12

The sample 1 was produced in the same manner as in Example 1, and the sample 1 was heated for 30 minutes on a hot plate heated to a temperature of 230° C., thereby curing the rib member. Subsequently, the sample 1 after curing of the rib member was cut between the rib members with a dicing blade to obtain ribbed substrates (singulated sample 1) of Example 12. Subsequently, the ribbed substrate and the semiconductor substrate laminated product were laminated with an epoxy-based adhesive interposed therebetween, thereby obtaining a third laminate. As the semiconductor substrate laminated product, a semiconductor substrate laminated product was used in which a semiconductor substrate provided with a light receiving element and a wiring substrate are bonded with a die bond material interposed therebetween, and an electrode pad on the semiconductor substrate and an electrode pad on the wiring substrate are electrically connected through a metallic wire. The lamination was performed such that the epoxy-based adhesive was interposed between the rib member and the semiconductor substrate laminated product. The epoxy-based adhesive used was a thermosetting adhesive containing bisphenol A diglycidyl ether as a main agent, and an imidazole-based curing agent as a curing agent, where the weight ratio of the main agent to the curing agent (main agent/curing agent) is 100/3.

Subsequently, the third laminate was heated in an oven at 200° C. for 2 hours, a peripheral portion of the rib member (a region including a wire) was then sealed with a sealing resin, and a solder ball was formed on a surface of the wiring substrate on a side opposite to the semiconductor substrate to obtain an optical semiconductor device of Example 12. The optical semiconductor device of Example 12 had a structure shown in FIG. 8. In the optical semiconductor device of Example 12, the thickness of the rib member was 50 μm, and the thickness of the adhesive layer was 10 μm.

### Example 13

A ribbed substrate of Example 13 and an optical semiconductor device of Example 13 were each produced in the same manner as in Example 12 except that a photosensitive composition PS2 was used instead of the photosensitive composition PS1.

### Example 14

A ribbed substrate of Example 14 and an optical semiconductor device of Example 14 were each produced in the same manner as in Example 12 except that a photosensitive composition PS5 was used instead of the photosensitive composition PS1.

### Comparative Example 2

A ribbed substrate of Comparative Example 2 and an optical semiconductor device of Comparative Example 2 were each produced in the same manner as in Example 12 except that a photosensitive composition PS12 was used instead of the photosensitive composition PS1.

### Comparative Example 3

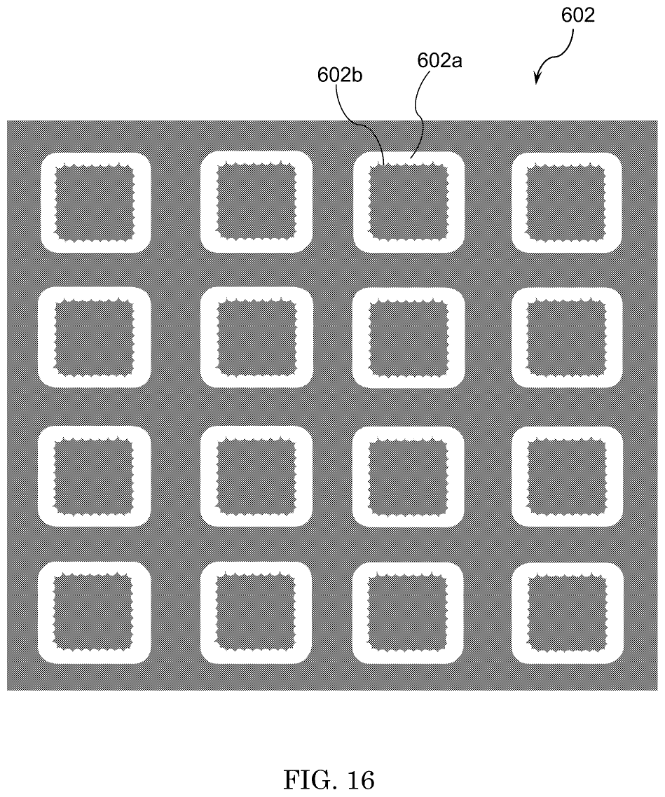

A ribbed substrate of Comparative Example 3 and an optical semiconductor device of Comparative Example 3 were each produced in the same manner as in Example 1 except that the photosensitive composition PS12 was used instead of the photosensitive composition PS1, and a photomask 602 shown in FIG. 16 was used instead of the photomask 601 shown in FIG. 15. The photomask 602 shown in FIG. 16 had a light-transmitting region 602a having a width of 200 am. An irregular shape having an arithmetic mean roughness Ra of 5,000 nm was formed on an inner surface 602b of the light-transmitting region 602a, and the irregular shape was formed only in a direction perpendicular to the thickness direction of the photomask 602.

### <Method for Measuring and Evaluating Physical Properties>

Next, methods for measuring and evaluating various physical properties will be described.

### [Patterning Property]

The pattern shape of the rib member of the sample 1 was observed with a 3D measurement laser microscope (“LEXT (registered trademark) OLS4000” manufactured by Olympus Corporation) and a stylus type surface profile measuring instrument (“Dektak (registered trademark) 150” manufactured by Veeco Instruments Inc.), and evaluated in accordance with the following criteria.
A: Either a residue or peeling did not occur between patterns.
B: One of a residue and peeling occurred between patterns.

### [Surface Shape]

The arithmetic mean roughness Ra of each of an inner peripheral surface and an end surface of the rib member of the ribbed substrate (evaluated length: 20 μm) and the skewness Ssk of the inner peripheral surface of the rib member of the ribbed substrate were measured using a 3D measurement laser microscope (“LEXT (registered trademark) OLS5100” manufactured by Olympus Corporation). For the arithmetic mean roughness Ra of the inner peripheral surface of the rib member, the arithmetic mean roughness Ra in a direction perpendicular to the thickness direction of the glass substrate and the arithmetic mean roughness Ra in a direction parallel to the thickness direction of the glass substrate were measured. For the measurement of the skewness Ssk, ten measurement locations (square regions of 20 μm×20 μm) were randomly selected on the inner peripheral surface of the rib member, the skewness Ssk was measured at the selected measurement locations, and the arithmetic average of the obtained ten measured values was taken as an evaluation value (skewness Ssk shown in Tables 3 to 5 below).

### [Reaction Ratio]

First, solid ¹³C-NMR charts of the solid contents of photosensitive compositions PS1 to PS13 were obtained by following the analysis conditions shown below. The area of a peak originating in the “cationically polymerizable group of the curable compound” in the obtained NMR chart was determined, and the obtained peak area was defined as a “first peak area.” Next, a solid ¹³C-NMR chart of the rib member of the ribbed substrate (a rib member having a mass equal to that of the sample for which the first peak area was measured) was obtained by following the analysis conditions shown below. The area of a peak originating in the “cationically polymerizable group of the curable compound” in the obtained NMR chart was determined, and the obtained peak area was defined as a “second peak area.” The reaction ratio (unit: %) was calculated from the equation “reaction ratio=(1−second peak area/first peak area)×100.” The reaction ratio thus obtained is a reaction ratio of the curable compound in the rib member before the semiconductor substrate and the glass substrate are bonded to each other.

### (Solid ¹³C-NMR Analysis Conditions)

Measuring apparatus: nuclear magnetic resonance analyzer (“VNMRS 600” manufactured by Agilent Technologies, Inc.)
Resonance frequency: 150.85 MHz
Measurement mode: DP/MAS method (direct polarization method)
Rotation speed of measurement sample: 20 kHz
Measurement temperature: 25° C.
Cumulative number: 4096
Relaxation delay: 15.000 sec
FID acquisition time: 0.015 sec
Flip angle: 90°

### [Die Shear Strength]

Using a die shear tester (“SERIES 4000” manufactured by Nordson DAGE), a shear force was applied to the optical semiconductor device (specifically, a shear force was applied to the glass substrate and the semiconductor substrate) to measure a load under which the semiconductor substrate was peeled from the optical semiconductor device. The maximum value of the load was defined as a die shear strength. The die shear strength was measured under the conditions of a shear height of 50 μm and a shear speed of 80 μm/sec in accordance with MIL STD 883.

### [Ghost Index]

First, for an optical semiconductor device to be evaluated, the number of pixels exceeding a predetermined threshold value (1/100 million of the brightness of a light source) (hereinafter, referred to as a “number of abnormal pixels”) was determined using a ghost flare evaluation system (“GCS-2T” manufactured by TSUBOSAKA ELECTRIC Co., Ltd.), and the number of abnormal pixels was divided by the number of all pixels to calculate the value of the number of abnormal pixels/the number of all pixels. Hereinafter, the value obtained by dividing the number of abnormal pixels by the number of all pixels (the number of abnormal pixels/the number of all pixels) may be referred to as an abnormal pixel number ratio.

The abnormal pixel number ratio in Comparative Example 1 was defined as 100, the ratio of each of the numbers of abnormal pixels in Examples 1 to 15 and Comparative Examples 2 and 3 was normalized, and the normalized value (hereinafter, referred to as a “ghost index”) was used as an index of performance enabling suppression of generation of ghosts. When the ghost index was 80 or less, it was determined that generation of ghosts was suppressed. On the other hand, when the ghost index was more than 80, it was determined that generation of ghosts was not suppressed.

### [Stability of Semi-Cured State]

First, the surface elastic modulus of an end surface of a rib member of a ribbed substrate to be evaluated (ribbed substrate before storage in a thermostat) was measured by a method shown in (Method for measuring a surface elastic modulus) below. Hereinafter, the surface elastic modulus measured here is sometimes referred to as an “initial surface elastic modulus.” Subsequently, the ribbed substrate was stored for 30 days in a thermostat set at a temperature of 40° C., and the surface elastic modulus of the end surface of the rib member of the ribbed substrate after storage was measured by the method shown in (Method for measuring a surface elastic modulus) below. Hereinafter, the surface elastic modulus measured here is sometimes referred to as an “surface elastic modulus after storage.” The ratio of change in surface elastic modulus (unit: %) was calculated from the equation “ratio of change in surface elastic modulus=100×surface elastic modulus after storage/initial surface elastic modulus.” When the ratio of change in surface elastic modulus was 100% or less, it was evaluated that the semi-cured state of the rib member was stably maintained (grade A). On the other hand, when the ratio of change in surface elastic modulus was more than 100%, it was evaluated that the semi-cured state of the rib member was not stably maintained (grade B).

### (Method for Measuring Surface Elastic Modulus)

The ribbed substrate was placed on a measurement stand of a measuring apparatus such that the rib member of the ribbed substrate faced upward. Next, a load was gradually applied to the rib member from above with an indenter, and the displacement against each load (depth to which the rib member was depressed with the indenter) was measured to obtain a load-displacement curve. The Young's modulus was calculated from the obtained load-displacement curve, and the calculated Young's modulus was defined as a surface elastic modulus. Detailed measurement conditions are as follows.
Measuring apparatus: nanoindentation tester (“ENT-NEXUS (registered trademark)” manufactured by ELIONIX INC.)
Temperature of ribbed substrate during measurement (temperature of measurement environment): 100° C.
Indenter approaching rate: 100 nm/sec
Maximum load: 1 mN
Load application rate: 0.6 mN/sec
Maximum load holding time: 5 seconds
Unloading rate: 0.6 mN/sec
Stiffness calculation: At unloading by 10% from the maximum load
Drift calculation: At unloading by 90% from the maximum load

### Results

For each of Examples 1 to 15 and Comparative Examples 1 to 3, the type of the photosensitive composition used, the type of the photomask used, the result of evaluating the patterning property, the result of measuring the surface shape, the presence or absence of an adhesive layer, the reaction ratio, the die shear strength, the ghost index, and the result of evaluating the stability of the semi-cured state are shown in Tables 3 to 5. In Tables 3 to 5, the numerical symbol “601” means the photomask 601 (see FIG. 15). In Table 5, the numerical symbol “602” means the photomask 602 (see FIG. 16). In Tables 3 to 5, “perpendicular direction Ra” means the arithmetic mean roughness Ra in a direction perpendicular to the thickness direction of the glass substrate, among the arithmetic mean roughnesses Ra of the inner peripheral surface of the rib member. In Tables 3 to 5, “parallel direction Ra” means the arithmetic mean roughness Ra in a direction parallel to the thickness direction of the glass substrate, among the arithmetic mean roughnesses Ra of the inner peripheral surface of the rib member. In Tables 3 to 5, “end surface Ra” means the arithmetic mean roughness Ra of the end surface of the rib member. In Tables 4 and 5, “-” means that evaluation was not performed.

TABLE 3

| | | Example | | | | | |
|---|---|---|---|---|---|---|---|
| | | 1 | 2 | 3 | 4 | 5 | 6 |
| Type of photosensitive composition | | PS1 | PS2 | PS3 | PS4 | PS5 | PS6 |
| Type of photomask | | 601 | 601 | 601 | 601 | 601 | 601 |
| Patterning property | | A | A | A | A | A | A |
| Surface | Perpendicular direction | 501 | 528 | 382 | 421 | 96 | 837 |
| shape | Ra [nm] | | | | | | |
| | Parallel direction Ra [nm] | 490 | 531 | 368 | 413 | 94 | 844 |
| | End surface Ra [nm] | 522 | 509 | 390 | 466 | 95 | 850 |
| | Skewness Ssk | −0.32 | −0.38 | −0.51 | −0.35 | −0.22 | −0.45 |

| | | | | | | |
|---|---|---|---|---|---|---|
| Presence or absence of adhesive | Absent | Absent | Absent | Absent | Absent | Absent |
| layer | | | | | | |
| Reaction ratio [%] | 35 | 32 | 35 | 33 | 37 | 33 |
| Die shear strength [kgf] | 23 | 27 | 24 | 26 | 21 | 22 |
| Ghost index | 38 | 35 | 45 | 43 | 75 | 49 |
| Stability of semi-cured state | B | B | B | B | B | B |

TABLE 4

| | | Example | | | | | |
|---|---|---|---|---|---|---|---|
| | | 7 | 8 | 9 | 10 | 11 | 12 |
| Type of photosensitive composition | | PS7 | PS8 | PS9 | PS10 | PS11 | PS1 |
| Type of photomask | | 601 | 601 | 601 | 601 | 601 | 601 |
| Patterning property | | A | A | A | A | A | A |
| Surface | Perpendicular direction | 1101 | 581 | 534 | 551 | 564 | 447 |
| shape | Ra [nm] | | | | | | |
| | Parallel direction Ra [nm] | 1089 | 574 | 520 | 547 | 558 | 454 |
| | End surface Ra [nm] | 1031 | 572 | 541 | 544 | 561 | 435 |
| | Skewness Ssk | −0.44 | −0.39 | −0.54 | −0.28 | −0.61 | −0.38 |

| | | | | | | |
|---|---|---|---|---|---|---|
| Presence or absence of adhesive | Absent | Absent | Absent | Absent | Absent | Present |
| layer | | | | | | |
| Reaction ratio [%] | 33 | 1 | 1 | 2 | 2 | 95 |
| Die shear strength [kgf] | 22 | 25 | 23 | 23 | 24 | 55 |
| Ghost index | 68 | 37 | 35 | 36 | 36 | 43 |
| Stability of semi-cured state | B | A | A | A | A | — |

TABLE 5

| | | Example | | | Comparative Example | | |
|---|---|---|---|---|---|---|---|
| | | 13 | 14 | 15 | 1 | 2 | 3 |
| Type of photosensitive composition | | PS2 | PS5 | PS13 | PS12 | PS12 | PS12 |
| Type of photomask | | 601 | 601 | 601 | 601 | 601 | 602 |
| Patterning property | | A | A | B | A | A | A |
| Surface | Perpendicular direction | 481 | 98 | 732 | 12 | 10 | 5017 |
| shape | Ra [nm] | | | | | | |
| | Parallel direction Ra [nm] | 479 | 96 | 745 | 7 | 8 | 9 |
| | End surface Ra [nm] | 476 | 93 | 788 | 12 | 9 | 10 |
| | Skewness Ssk | −0.43 | −0.27 | 0.68 | 0.02 | 0.02 | 16.55 |

| | | | | | | |
|---|---|---|---|---|---|---|
| Presence or absence of adhesive | Present | Present | Absent | Absent | Present | Absent |
| layer | | | | | | |
| Reaction ratio [%] | 97 | 96 | 2 | 35 | 96 | 37 |
| Die shear strength [kgf] | 56 | 53 | 10 | 16 | 42 | 17 |
| Ghost index | 40 | 76 | 60 | 100 | 102 | 82 |
| Stability of semi-cured state | — | — | A | B | B | B |

As shown in Tables 3 to 5, the arithmetic mean roughness Ra of the inner peripheral surface of the rib member was 50 nm or more and 3,000 nm or less in both the direction perpendicular to the thickness direction of the glass substrate and the direction parallel to the thickness direction of the glass substrate in Examples 1 to 15. As shown in Tables 3 to 5, the ghost index was 80 or less in Examples 1 to 15. Thus, the optical semiconductor devices of Examples 1 to 15 suppressed generation of ghosts.

As shown in Table 5, the arithmetic mean roughness Ra of the inner peripheral surface of the rib member was less than 50 nm or more than 3,000 nm in both the direction perpendicular to the thickness direction of the glass substrate and the direction parallel to the thickness direction of the glass substrate in Comparative Examples 1 to 3. As shown in Table 5, the ghost index was more than 80 in Comparative Examples 1 to 3. Thus, the optical semiconductor devices of Comparative Examples 1 to 3 did not suppress generation of ghosts.

The above results show that the present invention can provide an optical semiconductor device which can suppress generation of optical noise.

### DESCRIPTION OF REFERENCE CHARACTERS

10 ribbed substrate
11 transparent substrate
12 rib member
13 light receiving element
14 semiconductor substrate
50, 100, 300, 350 optical semiconductor device
301 adhesive layer

1. A ribbed substrate comprising:
a transparent substrate; and
a rib member provided on one principal surface of the transparent substrate, wherein
the rib member is formed in a frame shape, and
an arithmetic mean roughness Ra of an inner peripheral surface of the rib member is 50 nm or more and 3,000 nm or less.

2. The ribbed substrate according to claim 1, wherein a value of a skewness Ssk of the inner peripheral surface of the rib member is negative.

3. The ribbed substrate according to claim 1, wherein the arithmetic mean roughness Ra of the inner peripheral surface of the rib member is 200 nm or more and 900 nm or less.

4. The ribbed substrate according to claim 1, wherein a content ratio of a filler in the rib member is 30 wt % or less based on a total amount of the rib member.

5. The ribbed substrate according to claim 1, wherein an arithmetic mean roughness Ra of an end surface of the rib member on a side opposite to the transparent substrate side is 50 nm or more and 3,000 nm or less.

6. The ribbed substrate according to claim 1, wherein the transparent substrate is a glass substrate.

7. The ribbed substrate according to claim 1, wherein the rib member includes a cured product of a photosensitive composition, and the photosensitive composition contains a curable compound having a polymerizable group, and a photopolymerization initiator, and has alkali solubility.

8. The ribbed substrate according to claim 7, wherein the photosensitive composition has a linear structure and a cyclic structure.

9. The ribbed substrate according to claim 8, wherein the photosensitive composition contains a polysiloxane compound having the linear structure.

10. The ribbed substrate according to claim 7, wherein the photosensitive composition contains, as the curable compound, a compound having one or more cationically polymerizable groups selected from the group consisting of a glycidyl group and an alicyclic epoxy group.

11. The ribbed substrate according to claim 7, wherein
the photosensitive composition contains, as the curable compound, a compound having one or more cationically polymerizable groups selected from the group consisting of a glycidyl group and an alicyclic epoxy group, and a compound having a radically polymerizable group, and
the photopolymerization initiator is a photoradical polymerization initiator.

12. The ribbed substrate according to claim 7, wherein the photosensitive composition contains a compound having one or more alkali-soluble groups selected from the group consisting of a monovalent organic group of the following chemical formula (X1), a divalent organic group of the following chemical formula (X2), a phenolic hydroxyl group, and a carboxy group.

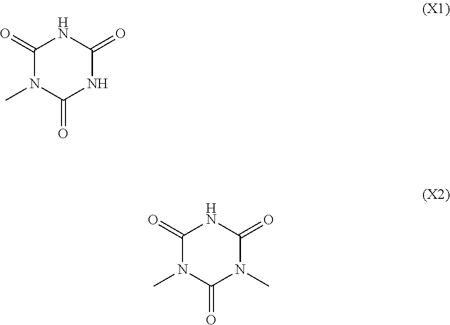

13. An optical semiconductor device comprising:
the ribbed substrate according to claim 1; and
a semiconductor substrate provided with a light receiving element, wherein
the transparent substrate of the ribbed substrate and the semiconductor substrate are laminated with the rib member of the ribbed substrate interposed therebetween, and
the rib member is provided so as to surround the light receiving element.

14. The optical semiconductor device according to claim 13, further comprising an adhesive layer that bonds the rib member and the semiconductor substrate together.
